(19) United States
(12) Patent Application Publication
(10) Pub. No.: US 2025/0309663 A1
(43) Pub. Date: Oct. 2, 2025

(54) ELECTRONIC DEVICE AND METHOD FOR OPERATING THE SAME

(71) Applicant: SAMSUNG ELECTRONICS CO., LTD., Suwon-si (KR)

(72) Inventors: Byeonghyun JANG, Suwon-si (KR); Seungduck NOH, Suwon-si (KR); Jihyeok CHOI, Suwon-si (KR)

(21) Appl. No.: 19/169,614

(22) Filed: Apr. 3, 2025

Related U.S. Application Data
(63) Continuation of application No. PCT/KR2025/003666, filed on Mar. 21, 2025.

(30) Foreign Application Priority Data
Apr. 2, 2024 (KR) 10-2024-0044805
Jul. 2, 2024 (KR) 10-2024-0086713

(51) Int. Cl. H02J 7/00

(52) U.S. Cl. CPC H02J 7/0031; H02J 7/007188

(57) ABSTRACT

The disclosure provides an electronic device including a power control circuit. The power control circuit may be electrically connected to the connector and include a first signal path and a second signal path. The first signal path may include a first port electrically connected to the first pin and a first internal signal path portion connected to the first port and configured to transfer the power supplied from the external electronic device to the battery, and the second signal path may include a second port electrically connected to the second pin and a second internal signal path portion configured to selectively connect the second port or a ground. The second internal signal path portion may be configured so that the second port is electrically disconnected from the ground and the power is not supplied from the external electronic device through the first pin or a voltage value of the power is decreased, based on a presence of moisture in the connector while the external electronic device is connected to the connector.

### CROSS-REFERENCE TO RELATED APPLICATIONS

This application is a continuation of International Application No. PCT/KR2025/003666 designating the United States, filed on Mar. 21, 2025, in the Korean Intellectual Property Receiving Office, and claiming priority to Korean Patent Application Nos. 10-2024-0044805, filed on Apr. 2, 2024, and 10-2024-0086713, filed on Jul. 2, 2024, in the Korean Intellectual Property Office, the disclosures of each of which are incorporated by reference herein in their entireties.

### BACKGROUND

### Field

The disclosure relates to an electronic device and a method for operating the electronic device.

### Description of Related Art

Various electronic devices, such as a smart phone and a tablet PC, have an interface (e.g., a connector) for connecting an external electronic device to the electronic device in a wired manner. Interfaces for device connection are standardized by various standards. Among various standards, universal serial bus (USB) is widely used. USB is an industry standard that allows data exchange and delivery of power between many types of electronic devices.

When an interface, such as a connector, is used for wired connection between devices, it is necessary to consider a method for identifying that a foreign substance (e.g., moisture) is introduced into the connector and preventing/reducing corrosion of the connector due to the inflow of the foreign substance.

The above-described information may be provided as related art for aiding in understanding of the disclosure. No assertion or determination is made as to whether the foregoing is prior art related to the disclosure.

### SUMMARY

According to an example embodiment, there may be provided an electronic device comprising: a battery, a connector, and/or a power control circuit. The connector may include: a first pin and a second pin spaced apart from each other and configured to be connected to an external electronic device. The first pin may be configured to receive power for charging the battery from the external electronic device. The power control circuit may be electrically connected to the connector and include a first signal path and a second signal path. The first signal path may include a first port electrically connected to the first pin and a first internal signal path portion connected to the first port and configured to transfer the power supplied from the external electronic device to the battery. The second signal path may include a second port electrically connected to the second pin and a second internal signal path portion configured to selectively connect the second port and a ground. The second internal signal path portion may be configured so that the second port is electrically disconnected from the ground and the power is not supplied from the external electronic device through the first pin or a voltage value of the power is decreased, based on a presence of moisture in the connector while the external electronic device is connected to the connector.

According to an example embodiment, there may be provided an electronic device comprising: a battery, a connector, a power management module comprising power management circuitry, a memory including one or more storage media storing instructions, and/or at least one processor, comprising processing circuitry. The connector may include a first pin, a second pin, and a third pin configured to be connected to an external electronic device. The power management module may be electrically connected to the connector and may include a first circuit, a second circuit, and/or a third circuit. The first circuit may be connected to a first port electrically connected to the first pin and be configured to transfer power supplied from the external electronic device through the first pin to the battery. The second circuit may be connected to a second port electrically connected to the second pin and be configured to selectively connect the second port and the ground. The third circuit may be connected to a third port electrically connected to the third pin and be configured to transmit a signal to the external electronic device through the third port. At least one processor, individually and/or collectively, may be configured to execute the instructions and to cause the electronic device to perform at least one operation. The at least one operation may include identifying that moisture is present in the connector. The at least one operation may include identifying that the external electronic device is connected to the electronic device through the connector. The at least one operation may include, based on identifying that the moisture is present in the connector and the external electronic device is connected to the electronic device through the connector, outputting a request signal for not supplying the power from the external electronic device through the first pin or for decreasing a voltage value of the power through the third port. The at least one operation may include determining whether a first voltage value supplied through the first pin is greater than or equal to a first reference voltage after a specified time elapses after the request signal is output through the third port. The at least one operation may include electrically disconnecting the second port from the ground, based on determining that the first voltage value is greater than or equal to the first reference voltage.

According to an example embodiment, a method for operating an electronic device may be provided. The method may include identifying that moisture is present in the connector. The method may include identifying that the external electronic device is connected to the electronic device through the connector. The method may include, based on identifying that the moisture is present in the connector and the external electronic device is connected to the electronic device through the connector, outputting a request signal for not supplying the power from the external electronic device through a first pin or for decreasing a voltage value of the power through a third port. The method may include determining whether a first voltage value supplied through the first pin is greater than or equal to a first reference voltage after a specified time elapses after the request signal is output through the third port. The method may include electrically disconnecting a second port from ground, based on determining that the first voltage value is greater than or equal to the first reference voltage.

According to an example embodiment, there may be provided a non-transitory computer-readable storage medium storing at least one instruction. The at least one instruction, when executed by at least one processor, comprising processing circuitry of an electronic device, individually and/or collectively, may cause the electronic device to perform at least one operation. The at least one operation may include: identifying that moisture is present in a connector. The at least one operation may include identifying that an external electronic device is connected to the electronic device through the connector. The at least one operation may include, based on identifying that the moisture is present in the connector and the external electronic device is connected to the electronic device through the connector, outputting a request signal for not supplying the power from the external electronic device through the first pin or for decreasing a voltage value of the power through a third port. The at least one operation may include determining whether a first voltage value supplied through the first pin is greater than or equal to a first reference voltage after a specified time elapses after the request signal is output through the third port. The at least one operation may include electrically disconnecting a second port from ground, based on determining that the first voltage value is greater than or equal to the first reference voltage.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram illustrating an electronic device in a network environment according to various embodiments of the disclosure;

FIG. 2 is a perspective view illustrating a connector of an electronic device according to an embodiment;

FIG. 3A is a diagram including a perspective view illustrating a connector of an electronic device and a connector of an external electronic device according to an embodiment of the disclosure;

FIG. 3B is a diagram illustrating an example pin structure of a connector of an electronic device according to an embodiment;

FIG. 4 is a block diagram illustrating an example configuration of a system including an electronic device and an external electronic device according to an embodiment of the disclosure;

FIG. 5 is a block diagram illustrating an example configuration of a power control circuit of an electronic device according to an embodiment of the disclosure;

FIGS. 6A and 6B are circuit diagrams illustrating an example second control circuit included in a power control circuit of an electronic device according to an embodiment of the disclosure;

FIG. 7 is a circuit diagram illustrating an example first control circuit included in a power control circuit of an electronic device according to an embodiment of the disclosure;

FIG. 8 is a block diagram illustrating an example configuration of a power control circuit of an electronic device according to an embodiment of the disclosure;

FIG. 9 is a flowchart illustrating an example method of operating an electronic device according to an embodiment of the disclosure;

FIG. 10 is a flowchart illustrating an example method of operating an electronic device according to an embodiment of the disclosure;

FIG. 11 is a flowchart illustrating an example method of operating an electronic device according to an embodiment of the disclosure;

FIG. 12 is a flowchart illustrating an example method of operating an electronic device according to an embodiment of the disclosure;

FIG. 13 is a flowchart illustrating an example method of operating an electronic device according to an embodiment of the disclosure;

FIG. 14 is a flowchart illustrating an example method of operating an electronic device according to an embodiment of the disclosure;

FIG. 15 is a flowchart illustrating an example method of operating an electronic device according to an embodiment of the disclosure;

FIG. 16 is a flowchart illustrating an example method of operating an electronic device according to an embodiment of the disclosure;

FIG. 17 is a diagram illustrating an example screen in which an electronic device provides a guide message for disconnecting an external electronic device, according to an embodiment of the disclosure; and

FIG. 18 is a flowchart illustrating an example method of operating an electronic device according to an embodiment of the disclosure.

### DETAILED DESCRIPTION

Hereinafter, various example embodiments of the disclosure are described in greater detail with reference to the drawings. However, the disclosure may be implemented in other various forms and is not limited to the various example embodiments set forth herein. The same or similar reference denotations may be used to refer to the same or similar elements throughout the disclosure and the drawings. Further, for clarity and brevity, descriptions of well-known functions and configurations in the drawings and relevant descriptions may be omitted.

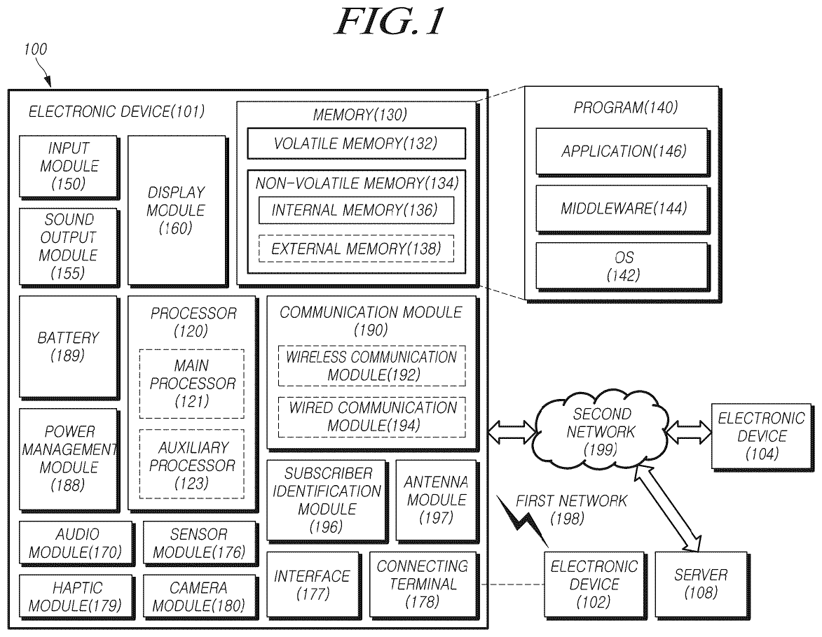

FIG. 1 is a block diagram illustrating an electronic device in a network environment according to various embodiments of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120 and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wired) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wired) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a communication module 192 (e.g., a cellular communication module, a short-range communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The communication module 192 may identify or authenticate the electronic device 101 in a communication network, such as the first network 198 or the second network 199, using subscriber information (e.g., international mobile subscriber identity (IMSI)) stored in the subscriber identification module 196.

The communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The communication module 192 may support a high-frequency band (e.g., the mmWave band) to achieve, e.g., a high data transmission rate. The communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The communication module 192 may support various requirements specified in the electronic device 101, an external electronic device (e.g., the electronic device 104), or a network system (e.g., the second network 199). According to an embodiment, the communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

According to an embodiment, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

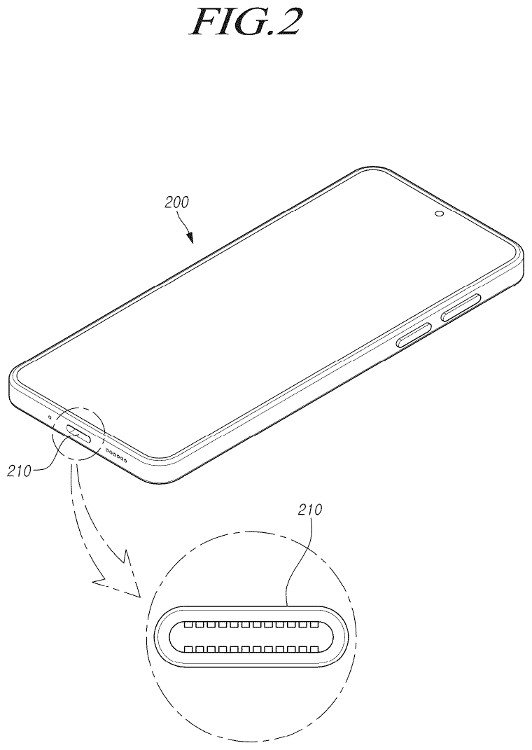

FIG. 2 is a perspective view illustrating a connector of an electronic device according to an embodiment.

According to an embodiment, an electronic device 200 (e.g., the electronic device 101 of FIG. 1) may be implemented as a portable electronic device such as a smartphone or a tablet PC, but is not limited thereto. The electronic device 200 may include a connector 210 (e.g., the interface 177 of FIG. 1 or the connecting terminal 178 of FIG. 1) to which an external electronic device may be connected.

According to an embodiment, the electronic device 200 may be connected to an external electronic device through the connector 210 and may transmit/receive information and/or data (e.g., multimedia data such as audio data and/or other control commands) to/from the connected external electronic device.

According to an embodiment, when the external electronic device, connected to the electronic device 200 through the connector 210, is a charging device (e.g., a charger), the electronic device 200 may receive power (or voltage) from the external electronic device and may charge the battery (e.g., the battery 189 of FIG. 1) using at least a portion of the supplied power.

According to an embodiment, the electronic device 200 may include an opening formed on one side (e.g., surface) of the housing and a hole connected to the opening, and the connector 210 may be disposed in the hole. For example, as illustrated in FIG. 2, an opening and a hole may be formed on the lower side of the housing of the electronic device 200, and the connector 210 may be disposed therein, but the disclosure is not limited thereto. For example, the connector 210 may be disposed on another side (e.g., surface) of the housing of the electronic device 200.

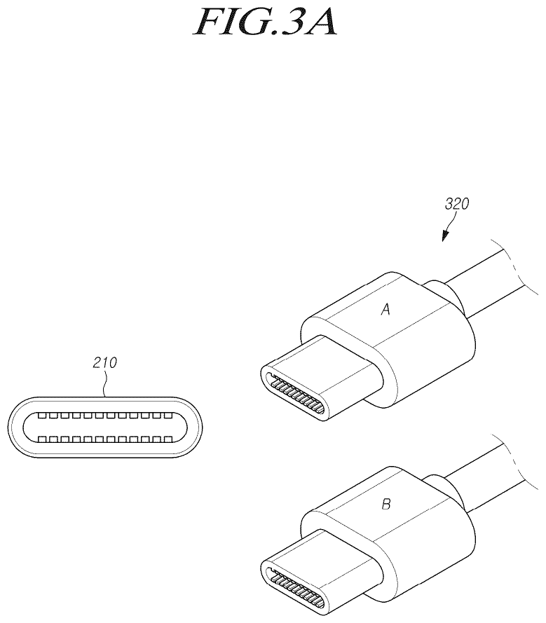

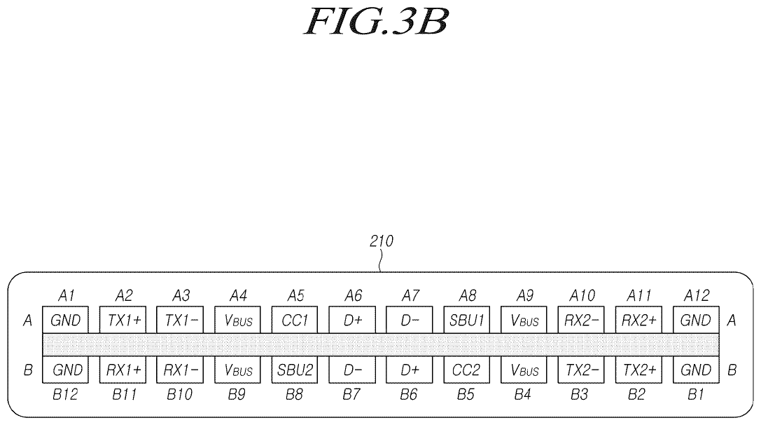

FIG. 3A is a diagram including a perspective view illustrating a connector of an electronic device and a connector of an external electronic device according to an embodiment of the disclosure. FIG. 3B is a diagram illustrating an example pin structure of a connector of an electronic device according to an embodiment of the disclosure.

Referring to FIG. 3A, a connector 320 of an external electronic device may be inserted into the connector 210 of the electronic device 200. According to an embodiment, the type of the external electronic device is not limited and may include, for example, a battery pack supplying power to the electronic device 200, a device communicating with the electronic device 200, or an external memory connected to the electronic device 200.

According to an embodiment, the connector 320 of the external electronic device may be received through a hole provided in the electronic device 200 to physically contact (e.g., connect to or with) the connector 210 of the electronic device 200 and may be electrically connected to the electronic device 200 based on physical contact.

According to an embodiment, the connector 210 and the hole structure of the electronic device 200 may be reversible. For example, the connector 210 may be symmetrical with respect to a first direction perpendicular to a direction in which the external electronic device is inserted (e.g., from the bottom to the top of the electronic device 200) and a second direction opposite to the first direction. That is, for example, the connector 210 may have two-fold rotational symmetry as the connector 210 may be connected in either of two orientations (e.g., right-side-up or upside-down).

As illustrated in FIG. 3A, one side or surface (e.g., surface A) of the connector 320 of the external electronic device may be inserted into the connector 210 of the electronic device 200 in a direction parallel to the front side or surface (e.g., the surface on which the display of the electronic device 200 is positioned) of the electronic device 200. That is, for example, after the connector 320 is inserted into the connector 210, surface A of the connector 320 may be positioned parallel to the surface on which the display of the electronic 200 is positioned. Alternatively, another side or surface (e.g., surface B) of the connector 320 of the external device may be inserted in a direction parallel to the front side or surface of the electronic device 200. That is, for example, after the connector 320 is inserted into the connector 210, surface B of the connector 320 may be positioned parallel to the surface on which the display of the electronic 200 is positioned.

According to an embodiment, the connector 210 may include a plurality of pins (or terminals). According to an embodiment, when the connector 320 of the external electronic device is inserted in different directions (e.g., upside down), each pin of the connector 320 of the external electronic device electrically connected to each pin included in the connector 210 of the electronic device 200 may be different.

According to an embodiment, the connector 210 and/or the connector 320 may be connectors according to USB standard. The connector 210 may be, e.g., a Type-C connector corresponding to the USB Type-C standard, but is not limited thereto. For example, a wired interface of various standards such as high-definition multimedia interface (HDMI), recommended standard 232 (RS232), power line communication, or plain old telephone service (POTS), or a non-standard wired interface may be applied to the connector 210 and/or the connector 320 of the disclosure. For example, a connector capable of transmitting data (e.g., data transmitted from a configuration channel 1 (CC1) pin and/or a configuration channel 2 (CC2) pin included in the USB Type-C standard) that may be used to automatically detect which devices are connected between a source device supplying power and a sink device receiving power or between a downstream facing port (DFP) providing data and an upstream facing port (UFP) receiving data may be applied to various embodiments.

As illustrated in FIG. 3B, the USB Type-C connector may have 12 pins on each of line (or row) A and line (or row) B, which may be symmetrical to each other.

According to an embodiment, the pins included in the connector 210 may be disposed to be spaced apart from each other. According to an embodiment, the electronic device 200 may transmit and/or receive a data signal through the A6(D+)/B6(D+) pin and/or the A7(D−)/B7(D−) pin of the connector 210. For example, the electronic device 200 (or the external electronic device) may transmit data to the external electronic device through the A6(D+)/B6(D+) pins. Since the role and/or function of each pin in various operation modes are defined by the USB Type-C standard, the role of each pin is omitted. In the disclosure, the D+pin may be referred to as a DP pin, and the D-pin may be referred to as a DN pin.

According to an embodiment, when the electronic device 200 is connected to the external electronic device, the electronic device 200 may exchange an electrical signal (e.g., a digital ID or a resistance ID) with the external electronic device through the pin A5 (CC1) and/or the pin B5 (CC2). For example, the electronic device 200 may detect the type of the external electronic device connected through the connector 210, based on the voltage value or the resistance value corresponding to the electrical signal.

According to an embodiment, the electronic device 200 may establish and/or manage a communication connection between the electronic device 200 and an external electronic device through the CC1 or CC2 pin. For example, the CC pin may be used to automatically detect which devices are connected between the source device and the sink device or between the DFP and the UFP. In the disclosure, the CC1 pin or the CC2 pin may be collectively referred to as a CC pin.

According to an embodiment, the electronic device 200 may detect moisture in the connector 210, based on the CC pin of the connector 210. For example, the electronic device 200 may detect moisture by identifying a resistance value corresponding to the CC pin as a resistance value corresponding to moisture.

According to an embodiment, the electronic device 200 may receive power or a power signal (e.g., power or voltage) from the external electronic device through the A4 (Vbus)/A9 (Vbus)/B4 (Vbus)/B9 (Vbus) pin. For example, the electronic device 200 may receive power or voltage from an external electronic device through the Vbus pin.

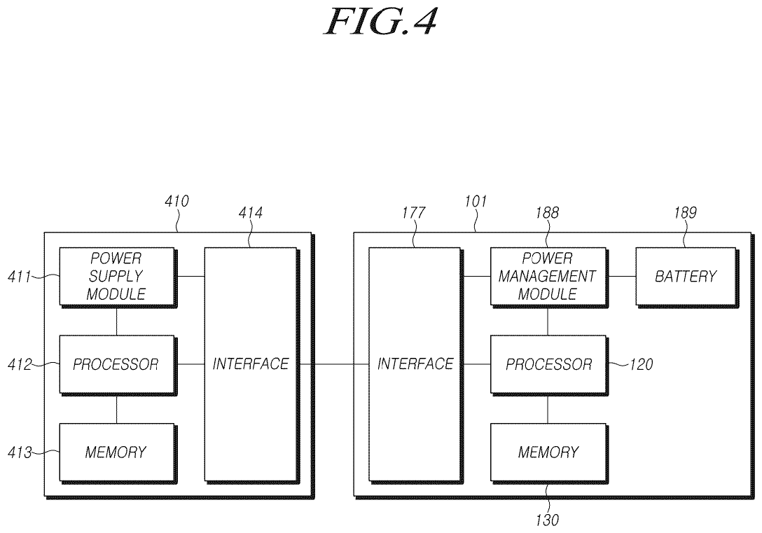

FIG. 4 is a block diagram illustrating an example configuration of a system including an electronic device and an external electronic device according to an embodiment of the disclosure.

Referring to FIG. 4, an electronic device 101 (e.g., the electronic device 200 of FIG. 2) may include a processor (e.g., including processing circuitry) 120, a memory 130, an interface (e.g., including circuitry) 177, a power management module (e.g., including power management circuitry) 188, and/or a battery 189.

According to an embodiment, the interface 177 may include at least one connector (e.g., the connector 210 of FIGS. 2 to 3B), and the electronic device 101 may be connected to an external electronic device 410 (e.g., a charging device) through the connector. The external electronic device 410 may include a connector (e.g., the connector 320 of FIG. 3A) corresponding to the connector of the electronic device 101 that may be connected to the interface 177.

According to an embodiment, the processor 120 of the electronic device 101 may include various processing circuitry and detect the connection of the external electronic device 410 and/or identify the type of the connected external electronic device 410 through the CC1 pin (e.g., the A5 (CC1) pin of FIG. 3B) and/or the CC2 pin (e.g., the B5 (CC2) pin of FIG. 3B) included in the interface 177. For example, the processor 120 may measure the voltage value and/or the resistance value corresponding to the external electronic device 410 through the CC1 pin and/or the CC2 pin, detect the connection of the external electronic device 410 based on the measured voltage value and/or resistance value, and/or identify the type (e.g., the data providing device or the source device) of the external electronic device 410. The description of the processor 120 provided above applies equally here.

According to an embodiment, the power management module 188 may include various power management circuitry and transfer power (or voltage) supplied from the external electronic device 410 to the battery 189 under the control of the electronic device 101 (or the processor 120 of the electronic device 101). At least a portion of the transferred power may be used to charge the battery 189.

According to an embodiment, the external electronic device 410 may include a power supply module (e.g., including power supply circuitry) 411, a processor (e.g., including processing circuitry) 412, a memory 413, and/or an interface (e.g., including interface circuitry) 414.

According to an embodiment, the interface 414 may include at least one connector (e.g., the connector 210 of FIGS. 2 to 3B), and the external electronic device 410 may be connected to the electronic device 101 through the connector.

According to an embodiment, the processor 412 of the external electronic device 410 may include various processing circuitry and detect the connection of the electronic device 101 and/or identify the type of the connected electronic device 101 through the CC1 pin and/or the CC2 pin provided in the interface 414. For example, the processor 412 may measure the voltage value and/or the resistance value corresponding to the electronic device 101 through the CC1 pin and/or the CC2 pin, detect the connection of the electronic device 101 based on the measured voltage value and/or resistance value, and/or identify the type (e.g., the sink device) of the electronic device 101. The description of the processor 120 provided above applies equally to the processor 412.

According to an embodiment, the external electronic device 410 may include a charging device (e.g., a PD charger) supporting a charging function. The external electronic device 410 may or may not support a protection function (e.g., hiccup function, but is not limited thereto).

According to an embodiment, the power supply module 411 may include a power supply circuit. The power supply module 411 (or the power supply circuit) may supply, e.g., power received from an external outlet or an internal battery to the electronic device 100 through a Vbus pin (e.g., the A5/A9/B4/B9 (Vbus) pin) of the interface 177.

According to an embodiment, the power supply module 411 (or power supply circuit) may include a pulse width modulation (PWM) module, an alternating current (AC) to direct current (DC) converter, and a synchronous rectifier. The PWM module may control the voltage of power received from an outlet (or an internal battery) through pulse width modulation. The AC/DC converter may convert an AC voltage received from the outlet into a DC voltage. The synchronous rectifier may enhance charging efficiency by converting a low-voltage direct current signal into a high-voltage direct current signal.

According to an embodiment, the power supply module 411 (or power supply circuit) may change the charging power (e.g., the charging voltage and/or the charging current) under the control of the processor 412.

According to an embodiment, the processor 412 may at least partially control each component included in the external electronic device 410.

According to an embodiment, when the external electronic device 410 is connected to the electronic device 101, the processor 412 of the external electronic device 410 may detect the connection with the electronic device 101 through the CC1 pin and/or the CC2 pin. According to an embodiment, in response to the connection with the electronic device 101, the processor 412 of the external electronic device 410 may apply a set voltage (e.g., about 5 V) to the electronic device 101 through the Vbus pin. The electronic device 101 may receive a voltage from the external electronic device 410 through the Vbus pin included in the interface 177. The processor 120 of the electronic device 101 may control the power management module 188 to charge the battery 189 based on the provided voltage.

According to an embodiment, the processor 120 of the electronic device 101 may detect moisture based on at least one pin (e.g., the CC1 pin, the CC2 pin, and/or the SBU pin of FIG. 3B) included in the interface 177. The SBU is a secondary bus pin and may include an SBU1 pin and an SBU2 pin, as illustrated in FIG. 3B. Hereinafter, a CC pin is described as an example of a pin used to sense moisture, but the disclosure is not limited thereto. For example, another type of pin (e.g., an SBU pin) may be used to detect moisture. For example, in addition to the pins of USB Type-C, a separate moisture sensing pin may be used to detect moisture.

According to an embodiment, the processor 120 may adjust the open/close state of the at least one switch so that the CC pin is changed to the open state. That the CC pin is in the open state may refer, for example, to the CC pin being in a high impedance state (e.g., a state in which a very high resistance value is applied) and may be a state in which no electrical signal is transmitted or received to or from the CC pin. As the CC pin is changed to the high impedance state, the processor 412 of the external electronic device 410 may not supply power to the electronic device 101.

According to an embodiment, the processor 412 of the external electronic device 410 may transmit an electrical signal to the CC pin of the electronic device 101, identify a connection with the electronic device 101 based on the electrical signal, and supply power to the electronic device 101. When the CC pin of the electronic device 101 is in the open state, the external electronic device 410 may not identify whether the electronic device 101 is connected, and may not supply power to the electronic device 101.

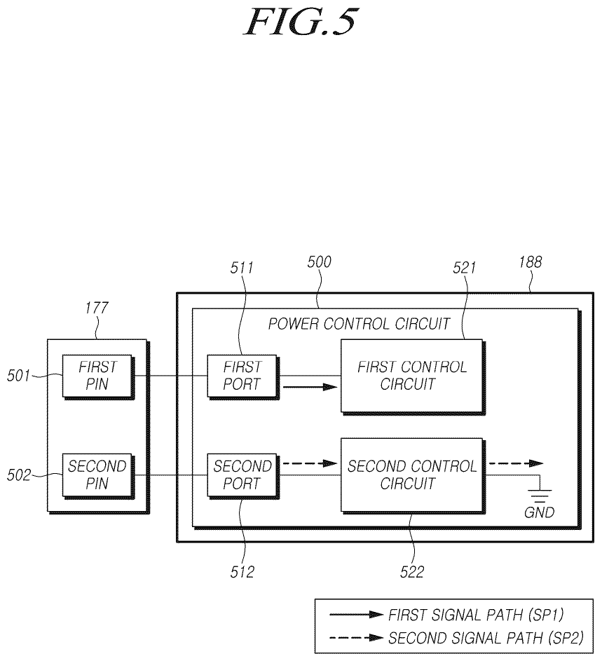

FIG. 5 is a block diagram illustrating an example configuration of a power control circuit of an electronic device according to an embodiment of the disclosure.

In the embodiment of FIG. 5, it may be understood that the operation(s) performed by the power control circuit 500 is/are performed under the control of an electronic device (e.g., the electronic device 101 of FIG. 1 or the electronic device 200 of FIG. 2) or a processor (e.g., the processor 120 of FIG. 1) of the electronic device.

According to an embodiment, the power control circuit 500 may be included in an electronic device (e.g., the electronic device 101 of FIG. 1 or the electronic device 200 of FIG. 2). For example, the power control circuit 500 may be included in a power management module (e.g., the power management module 188 of FIG. 1) of the electronic device.

According to an embodiment, the power control circuit 500 may include a plurality of ports (e.g., the first port 511 and the second port 512) and/or a plurality of control circuits (e.g., the first control circuit 521 and the second control circuit 522). In the disclosure, the first control circuit 521 may be referred as a first circuit, and the second control circuit 522 may be referred as a second circuit.

According to an embodiment, the power control circuit 500 may be electrically connected to the interface 177. The interface 177 may include, e.g., at least one connector (e.g., the connector 210 of FIGS. 2 to 3B).

According to an embodiment, the interface 177 may include a plurality of pins configured to be connected to an external electronic device (e.g., the external electronic device 410 of FIG. 4). For example, the interface 177 may include a first pin 501 and a second pin 502. The first pin 501 and the second pin 502 may be spaced apart from each other in the interface 177.

According to an embodiment, the first pin 501 may be used to receive power (or voltage) for charging a battery (e.g., the battery 189 of FIG. 1) of the electronic device from an external electronic device. The first pin 501 may be, e.g., the Vbus pin of FIG. 3B (e.g., the A4 pin, the A9 pin, the B4 pin, or the B9 pin of FIG. 3B).

According to an embodiment, the second pin 502 may be used to establish and/or manage a communication connection between the electronic device and the external electronic device. The second pin 502 may be, e.g., the CC pin of FIG. 3B (e.g., the A5 pin CC1 or the B5 pin CC2 of FIG. 3B).

According to an embodiment, each port may be electrically connected to a corresponding pin and a corresponding control circuit. For example, the first port 511 may be electrically connected to the first pin 501 and the first control circuit 521. For example, the second port 512 may be electrically connected to the second pin 502 and the second control circuit 522.

According to an embodiment, the power control circuit 500 (e.g., the power management module 188 of FIG. 4) may supply power, supplied from the external electronic device through the first pin 501, to the battery 189.

According to an embodiment, the first control circuit 521 may include a first circuit portion, electrically connected to the first port 511, to detect the voltage state of the first port 511 supplied from the external electronic device through the first pin 501.

According to an embodiment, the second control circuit 522 may include a second circuit portion electrically connected to the second port 512 and configured to selectively connect the second port 512 or the ground GND from the external electronic device.

According to an embodiment, the power control circuit 500 may include a signal path including a first signal path SP1 and/or a second signal path SP2. The signal transferred to the first signal path SP1 may include, e.g., a power signal. In the disclosure, the first signal path SP1 and the second signal path SP2 may be referred to as a first path and a second path, respectively.

According to an embodiment, the first signal path SP1 may be a signal path including the first port 511 electrically connected to the first pin 501. According to an embodiment, the second signal path SP2 may be a signal path including the second port 512 electrically connected to the second pin 502.

According to an embodiment, the first signal path SP1 may include a first port 511 electrically connected to the first pin 501 and a first internal signal path portion electrically connected to the first port 511 and configured to transfer power, supplied from the external electronic device through the first pin 501, to the battery 189.

According to an embodiment, the first signal path SP1 may include a first port 511 electrically connected to the first pin 501 and a first control circuit 521 electrically connected to the first port 511.

According to an embodiment, the second signal path SP2 may include a second port 512 electrically connected to the second pin 502 and a second internal signal path portion electrically connected to the second port 512 and configured to selectively connect the second port 512 or the ground GND. The second internal signal path portion may correspond to, e.g., the second circuit portion of the second control circuit 522 described above.

According to an embodiment, the power control circuit 500 may be configured so that the second port 512 is electrically disconnected from the ground GND and power is not supplied from the external electronic device through the first pin 501, or the voltage value of power supplied through the first pin 501 is decreased, based on the presence of moisture in the interface 177. For example, the second circuit portion (or the second internal signal path portion) of the second control circuit 522 may be configured so that the second port 512 is electrically disconnected from the ground GND and power is not supplied from the external electronic device through the first pin 501 or the voltage value of power supplied through the first pin 501 is decreased, based on the presence of moisture in the interface 177 while the external electronic device is connected to the interface 177. The voltage value of the power may be set to be lower (or less) than, e.g., a reference voltage value.

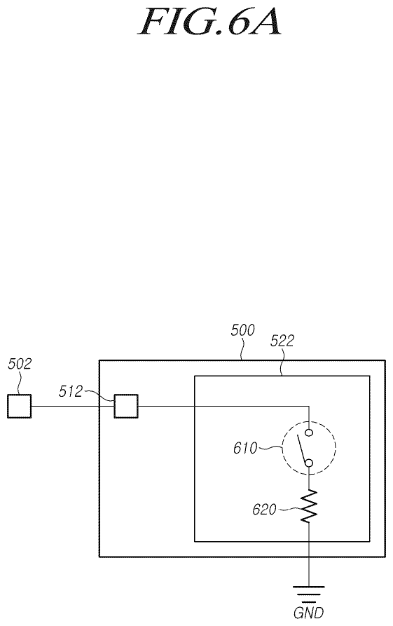

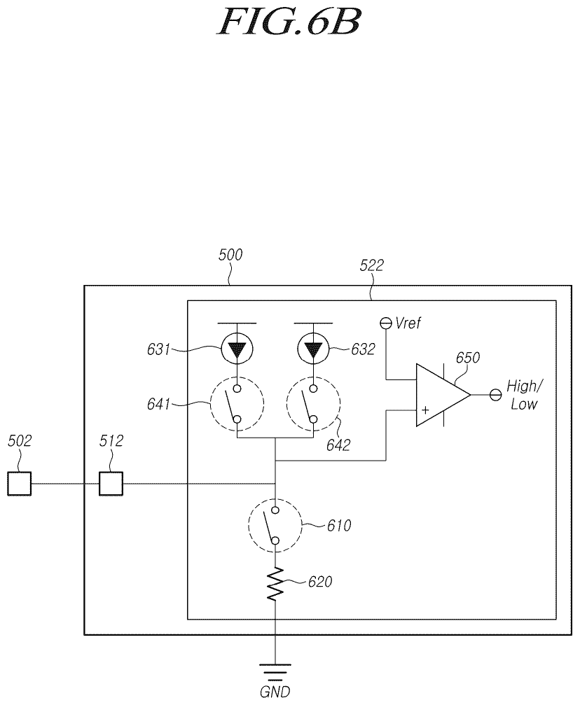

According to an embodiment, the second circuit portion (or the second internal signal path portion) of the second control circuit 522 may include a switch disposed between the second port 512 and the ground GND. The power control circuit 500 may be configured to perform electrical disconnection between the second port 512 and the ground GND based on the switch being opened. For example, the power control circuit 500 may electrically disconnect the second port 512 and the ground GND by setting the switch to the open state. The power control circuit 500 may be configured to perform an electrical connection between the second port 512 and the ground GND based on the switch being closed. For example, the power control circuit 500 may electrically connect the second port 512 and the ground GND by setting the switch to the close state. An example of the second control circuit 522 including a switch is described in greater detail below with reference to FIGS. 6A and 6B.

FIGS. 6A and 6B are circuit diagrams illustrating a second control circuit included in a power control circuit of an electronic device according to an embodiment of the disclosure.

In the embodiments of FIGS. 6A and 6B, the second control circuit may be an example of the second control circuit 522 included in the power control circuit 500 of FIG. 5. In the embodiments of FIGS. 6A and 6B, the second pin 502 may be, e.g., the CC pin of FIG. 3B.

In the embodiments of FIGS. 6A and 6B, it may be understood that the operation(s) performed by the power control circuit 500 is/are performed under the control of an electronic device (e.g., the electronic device 101 of FIG. 1 or the electronic device 200 of FIG. 2) or a processor (e.g., the processor 120 of FIG. 1) of the electronic device.

Referring to FIG. 6A, the second control circuit 522 may be electrically connected to the second port 512 and may include a switch 610 and/or a resistor 620.

According to an embodiment, the switch 610 may be disposed between the second port 512 and the ground GND and configured to selectively connect the second port 512 (or the second pin 502) or the ground GND. For example, the switch 610 may electrically connect or electrically disconnect the second port 512 and the ground GND depending on the open/close state of the switch 610.

According to an embodiment, the switch 610 may include, e.g., a bipolar junction transistor (BJT), a field-effect transistor (FET), a thyristor, a relay switch, an insulated gate bipolar transistor (IGBT), a micro-electro-mechanical systems switch (MEMS), or the like but is not limited thereto.

According to an embodiment, the power control circuit 500 may electrically disconnect the second port 512 and the ground GND by setting the open/close state of the switch 610 to the open state. The power control circuit may electrically connect the second port 512 and the ground GND by setting the open/close state of the switch 610 to the close state. According to an embodiment, the power control circuit 500 may set the open/close state of the switch 610 to be changed from the first state to the second state, thereby changing the connection state between the second port 512 and the ground GND. For example, the power control circuit 500 may set the open/close state of the switch 610 to be changed from the open state to the close state, thereby changing the connection state between the second port 512 and the ground GND from the electrically disconnected state to the electrically connected state. For example, the power control circuit 500 may set the open/close state of the switch 610 to be changed from the close state to the open state, thereby changing the connection state between the second port 512 and the ground GND to the electrically disconnected state.

According to an embodiment, based on identifying that the external electronic device (e.g., the external electronic device 410 of FIG. 4) is connected to the electronic device (e.g., the electronic device 101 of FIG. 1) through a connector (e.g., the interface 177 or the connector 210 of FIGS. 2 to 3B), the power control circuit 500 may set the switch 610 to the close state so that the second port 512 is electrically connected to the ground GND through the resistor 620.

According to an embodiment, the resistor 620 may be disposed between the switch 610 and the ground GND. The second port 512 (or the second pin 502) may be electrically connected to the ground GND through the resistor 620.

According to an embodiment, the resistor 620 may be a pull-down resistor Rd of the second pin 502 (or the second port 512). The resistor 620 may be set to, e.g., 5.1 (k (2).

According to an embodiment, the resistor 620 may be used for the external electronic device, connected to the electronic device through the connector, to detect the connection of the electronic device.

According to an embodiment, the resistor 620 may be used to negotiate charging between the electronic device, connected through the connector, and the external electronic device. For example, the resistor 620 may be used for the electronic device to operate as a sink device (e.g., a power consumer).

Referring to FIG. 6B, the second control circuit 522 may further include at least one current source (e.g., the first current source 631 and/or the second current source 632), at least one switch (e.g., the first switch 641 and/or the second switch 642) connected to the at least one current source, and/or a comparator 650. The description of the switch 610 and the resistor 620 of FIG. 6B may refer to the description of FIG. 6A, and a redundant description thereof may not be repeated here.

According to an embodiment, the first current value supplied by the first current source 631 may be different from the second current value supplied by the second current source 632. For example, the first current value (e.g., 1 μA), supplied by the first current source 631, may be less than the second current value (e.g., 80 μA), supplied by the second current source 632. In the disclosure, the first current source 631 and the second current source 632 may be together referred to as a current source, and the first switch 641 and the second switch 642 may be together referred to as a switch.

According to an embodiment, the switches 641 and 642 may selectively connect the corresponding current source 631 or 632 to the second port 512 (or the second pin 502). For example, the first switch 641 may electrically connect or disconnect the first current source 631 connected to the first switch 641 to/from the second pin 502. For example, the second switch 642 may electrically connect or disconnect the second current source 632 connected to the second switch 642 to/from the second pin 502.

According to an embodiment, the switch 641 or 642 may be, e.g., a BJT, a FET, a thyristor, a relay switch, an IGBT, or a MEMS switch, but is not limited thereto.

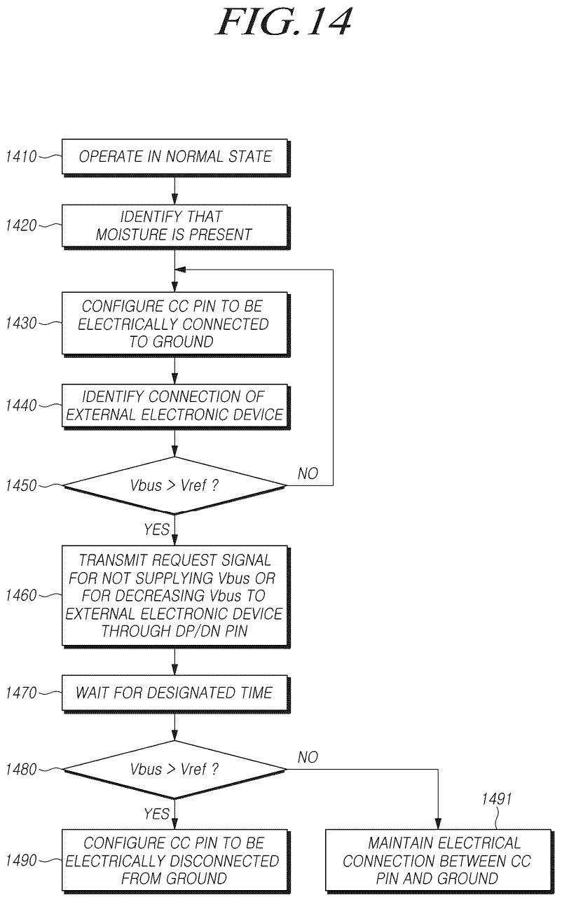

According to an embodiment, the switch 610, the first switch 641, and the second switch 642 may be synchronized (or associated) with each other. For example, in the normal state operation (e.g., the normal state operation of operation 1410 of FIG. 14), when any one of the switch 610, the first switch 641, and the second switch 642 operates in the close state, all of the other switches may operate in the open state. According to an embodiment, in the normal state operation, when the switch 610 operates in the close state, the first switch 641 and the second switch 642 may operate in the open state. In this case, the CC pin may be electrically connected to the ground through the resistor 620. According to an embodiment, in the normal state operation, when the first switch 641 operates in the close state, the switch 610 and the second switch 642 may operate in the open state. In this case, the first current source 631 may be connected to the CC pin and supply the first current value of the first current source 631 to the CC pin. According to an embodiment, in the normal state operation, when the second switch 642 operates in the close state, the switch 610 and the first switch 641 may operate in the open state. In this case, the second current source 632 may be connected to the CC pin, and the second current value of the second current source 632 may be supplied to the CC pin. Accordingly, only one component (e.g., the resistor 610, the first current source 631, or the second current source 632) may be connected to the second pin 502 at a time.

Table 1 illustrates an opening/closing operation of a switch in a normal state. The opening/closing operation of the switch in Table 1 is merely an example of the open/close state of the switch in the normal state, and the switch may be opened/closed in different manner.

TABLE 1

| | | First | Second |
|---|---|---|---|
| Time interval | Switch 610 | switch 641 | switch 642 |
| First time interval | Close state | Open state | Open state |
| Second time interval | Open state | Close state | Open state |
| Third time interval | Close state | Open state | Open state |

According to an embodiment, in the normal state, the CC pin (or the second control circuit 522) may periodically repeat the pull-up state and the pull-down state. Accordingly, in the normal state, the pull-up resistor Rp and the pull-down resistor Rd may be periodically connected to the CC pin. For example, as illustrated in Table 1, in the first time interval, the switch 610 may be in the close state, the second switch 641 and the second switch 642 may operate in the open state to be in the pull-down state, and in the second time interval which is the next time interval of the first time interval, the first switch 641 may operate in the close state, and the switch 610 and the second switch 642 may operate in the open state to be in the pull-up state. In the third time interval which is the next time interval of the second time interval, like the first time interval, the switch 610 may be in the close state, and the second switch 641 and the second switch 642 may operate in the open state to be in the pull-down state. As such, in the normal state, the pull-up state and the pull-down state may be periodically repeated under the control of the switch of the power control circuit 500. According to an embodiment, when the external electronic device is connected through the interface 177, the second control circuit 522 may control the third time interval operation to continue.

According to an embodiment, the second switch 642 may be omitted as an optional component. In this case, the operation in each time interval in Table 1 described above may be described only with the operation of the switch 610 and the second switch 641.

Table 2 illustrates an opening/closing operation of a switch in an abnormal state (e.g., a foreign substance or moisture detected state). The opening/closing operation of the switch in Table 2 is merely an example of the opening/closing operation of the switch in the abnormal state, and the switch may be opened/closed in another manner.

TABLE 2

| | | First | Second |
|---|---|---|---|
| Time interval | Switch 610 | switch 641 | switch 642 |
| Fourth time interval | Open state | Close state | Open state |
| Fifth time interval | Open state | Open state | Close state |
| Sixth time interval | Open state | Open state | Open state |

According to an embodiment, the power control circuit 500 may determine whether the CC pin is in the abnormal state in the close state of the first switch 641. For example, as illustrated in the fourth time interval of Table 2, the power control circuit 500 may operate the first switch 641 in the close state and the switch 610 and the second switch 642 in the open state and determine whether the CC pin is in the abnormal state based on the voltage value of the CC pin in the close state of the first switch 641.

According to an embodiment, based on determining that the CC pin is in the abnormal state in the close state of the first switch 641, the power control circuit 500 may change the second switch 642 from the open state to the close state and determine whether moisture is present in the open state of the second switch 642. For example, when it is determined that the CC pin is in the abnormal state in the close state of the first switch 641 (e.g., the switching state of the fourth time interval), the power control circuit 500 may operate the second switch 642 in the close state and the switch 610 and the first switch 641 in the open state, as illustrated in the fifth time interval of Table 2 and determine whether moisture is present in the CC pin in the abnormal state based on the voltage value of the CC pin. As such, e.g., when an abnormal state is detected in the switching state of the fourth time interval, an additional operation for moisture detection may be performed in the switching state of the fifth time interval. Based on determining that moisture is present in the close state of the second switch 642, the power control circuit 500 may set all of the switch 610, the first switch 641, and the second switch 642 to the open state. For example, when it is determined that moisture is present in the close state of the second switch 642 (e.g., the switching state of the fifth time interval), the power control circuit 500 may set all of the switch 610, the first switch 641, and the second switch 642 to the open state, as illustrated in the sixth time interval of Table 2. As such, e.g., when moisture is detected in the switching state of the fifth time interval, it may be switched to the switching state of the sixth time interval.

According to an embodiment, based on determining that the CC pin is in the abnormal state in the close state of the first switch 641, the power control circuit 500 may set all the switch 610, the first switch 641, and the second switch 642 to the open state. For example, when it is determined that the CC pin is in the abnormal state in the close state of the first switch 641 (e.g., the switching state of the fourth time interval), the power control circuit 500 may set all of the switch 610, the first switch 641, and the second switch 642 to the open state, as illustrated in the sixth time interval of Table 2. As such, e.g., when an abnormal state is detected in the switching state of the fourth time interval, it may be immediately switched to the switching state of the sixth time interval rather than operating in the switching state of the fifth time interval. According to an embodiment, after the switch 610, the first switch 641, and the second switch 642 are all opened, the power control circuit 500 may be configured to repeat the switching state of the fifth time interval and the switching state of the sixth time interval.

According to an embodiment, the second switch 642 may be omitted as an optional component. In this case, the operation in each time interval in Table 2 described above may be described only with the operation of the switch 610 and the first switch 641. For example, the switching operation of the fifth time interval between the fourth time interval and the sixth time interval in Table 2 may be omitted.

Table 3 illustrates an opening/closing operation of a switch in an abnormal state (e.g., a foreign substance or moisture detected state). The opening/closing operation of the switch in Table 3 is merely an example of the opening/closing operation of the switch in the abnormal state, and the switch may be opened/closed in different manner.

TABLE 3

| | | First | Second |
|---|---|---|---|
| Time interval | Switch 610 | switch 641 | switch 642 |
| Seventh time interval | Open state | Close state | Open state |
| Eighth time interval | Open state | Open state | Open state |
| Ninth time interval | Open state | Open state | Close state |
| Tenth time interval | Open state | Open state | Open state |

According to an embodiment, the power control circuit 500 may determine whether the CC pin is in the abnormal state in the close state of the first switch 641. For example, as illustrated in the seventh time interval of Table 3, the power control circuit 500 may operate the first switch 641 in the close state and the switch 610 and the second switch 642 in the open state and determine whether the CC pin is in the abnormal state based on the voltage value of the CC pin in the close state of the first switch 641.

According to an embodiment, based on determining that the CC pin is in the abnormal state in the close state of the first switch 641, the power control circuit 500 may change the second switch 642 from the open state to the close state and determine whether moisture is present. For example, in the close state of the first switch 641 (e.g., the switching state of the seventh time interval), the power control circuit 500 may operate the second switch 642 in the close state and the switch 610 and the first switch 641 in the open state, as illustrated in the ninth time interval of Table 3 and determine whether moisture is present in the CC pin in the abnormal state based on the voltage value of the CC pin. Based on determining that moisture is present in the close state of the second switch 642, the power control circuit 500 may set all the switch 610, the first switch 641, and the second switch 642 to the open state. For example, when it is determined that moisture is present in the close state of the second switch 642 (e.g., the switching state of the ninth time interval), the power control circuit 500 may set all of the switch 610, the first switch 641, and the second switch 642 to the open state, as illustrated in the tenth time interval of Table 3.

According to an embodiment, based on determining that the CC pin is in the abnormal state in the close state of the first switch 641, the power control circuit 500 may set all of the switch 610, the first switch 641, and the second switch 642 to the open state. For example, when it is determined that the CC pin is in the abnormal state in the open state of the first switch 641 (e.g., the switching state of the seventh time interval), the power control circuit 500 may set all of the switch 610, the first switch 641, and the second switch 642 to the open state, as illustrated in the eighth time interval of Table 3. In the state in which the switch 610, the first switch 641, and the second switch 642 are all opened, the power control circuit 500 may change the second switch 642 from the open state to the close state and determine whether moisture is present. For example, in the state in which the switch 610, the first switch 641, and the second switch 642 are all opened (e.g., the switching state of the eighth time interval), the power control circuit 500 may operate the second switch 642 in the close state and the switch 610 and the first switch 641 in the open state, as illustrated in the ninth time interval of Table 3, and determine whether moisture is present in the CC pin in the abnormal state based on the voltage value of the CC pin. Based on determining that moisture is present in the close state of the second switch 642, the power control circuit 500 may set all of the switch 610, the first switch 641, and the second switch 642 to the open state. For example, when it is determined that moisture is present in the close state of the second switch 642 (e.g., the switching state of the ninth time interval), the power control circuit 500 may set all of the switch 610, the first switch 641, and the second switch 642 to the open state, as illustrated in the tenth time interval of Table 3.

According to an embodiment, the second switch 642 may be omitted as an optional component. In this case, the operation in each time interval in Table 3 described above may be described only with the operation of the switch 610 and the first switch 641. For example, the switching operation of the ninth time interval between the eighth time interval and the tenth time interval in Table 3 may be omitted.

According to an embodiment, the first current source 631, the second current source 632, and/or the comparator 650 may be used to determine whether moisture is present in the second pin 502 (or the second port 512). For example, the power control circuit 500 may be configured to connect the first current source 631 to the second pin 502 through switch control (e.g., control the first switch 641 in the close state and the switch 610 and the second switch 642 in the open state) and determine whether the second pin 502 is in an abnormal state using the comparator 650 based on a first voltage value (or a first resistance value of the second pin 502 corresponding to the first voltage value) that is the voltage value of the second pin 502 obtained in a state in which the first current source 631 is connected to the second pin 502. The power control circuit 500 may determine, using the comparator 650, that it is in the abnormal state, e.g., when the first voltage value (or the first resistance value) is within a specified first range, and may determine that it is not in the abnormal state, when the first voltage value (or the first resistance value) is not within the specified first range. For example, based on determining that the second pin 502 is in the abnormal state, the power control circuit 500 may be configured to connect the second current source 632 to the second pin 502 through switch control (e.g., control the second switch 642 in the close state, and the switch 610 and the first switch 641 in the open state) and determine whether moisture is present in the second pin 502 using the comparator 650 based on the second voltage value (or the second resistance value of the second pin 502 corresponding to the second voltage value) that is the voltage value of the second pin 502 obtained in the state in which the second current source 632 is connected to the second pin 502. The power control circuit 500 may determine, using the comparator 650, that moisture is present, e.g., when the second voltage value (or the second resistance value) is within a specified second range, and determine that no moisture is present, when the second voltage value (or the second resistance value) is not within the specified second range. According to an embodiment, the specified first range for determining the abnormal state and the specified second range for determining the presence of moisture may be different ranges.

According to an embodiment, the comparator 650 may be used to monitor the voltage of the second pin 502 (or the second port 512). For example, the comparator 650 may obtain an output value (e.g., a high value (e.g., 1) or a low value (e.g., 0)) by comparing the voltage of the second pin 502 with a reference voltage Vref. The reference voltage of the comparator 650 may be set to be different or the same depending on a component (e.g., the resistor 620, the first current source 631, or the second current source 632 to the second pin 502) connected to the second pin 502.

According to an embodiment, the power control circuit 500 may be configured to monitor the voltage of the second pin 502 through the comparator 650 to identify whether the external electronic device is connected to the electronic device. The power control circuit 500 may be configured to monitor the voltage of the second pin 502 through the comparator 650 to identify a power profile that may be provided by the external electronic device. The power control circuit 500 may monitor the voltage of the second pin 502 through the comparator 650 to determine whether the resistance value corresponding to the second pin 502 is within a specified range. When the resistance value, corresponding to the second pin 502, is within the specified range, the power control circuit 500 may identify or determine that moisture is present in the connector. When the resistance value, corresponding to the second pin 502, is not within the specified range, the power control circuit 500 may identify or determine that moisture is not present in the connector.

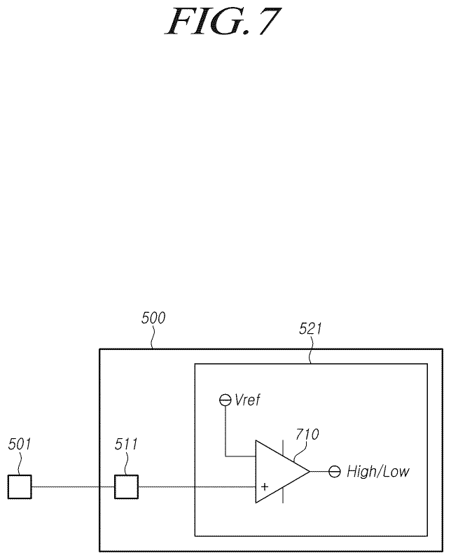

FIG. 7 is a circuit diagram illustrating a first control circuit included in a power control circuit of an electronic device according to an embodiment of the disclosure.

In the embodiment of FIG. 7, the first control circuit may be an example of the first control circuit 521 included in the power control circuit 500 of FIG. 5. In the embodiment of FIG. 7, the first pin 501 may be, e.g., the Vbus pin of FIG. 3B.

In the embodiment of FIG. 7, it may be understood that the operation(s) performed by the power control circuit 500 is/are performed under the control of an electronic device (e.g., the electronic device 101 of FIG. 1 or the electronic device 200 of FIG. 2) or a processor (e.g., the processor 120 of FIG. 1) of the electronic device.

Referring to FIG. 7, the first control circuit 521 may include a comparator 710.

According to an embodiment, the comparator 710 may be used to monitor the voltage of the first pin 501 (or the first port 511). For example, the comparator 710 may obtain an output value (e.g., a high or low value) by comparing the voltage Vbus of the first pin 501 with the reference voltage Vref.

According to an embodiment, the power control circuit 500 may monitor the voltage of the first pin 501 through the comparator 710 to determine whether power (or voltage) for charging a battery (e.g., the battery 189 of FIG. 1) is supplied from an external electronic device (e.g., the external electronic device 410 of FIG. 4) through the first pin 501. For example, when it is identified that the voltage value (Vbus value) of the first pin 501 is lower (or less) than the reference voltage value (Vref value) (e.g., output the low value (e.g., 0)), the power control circuit 500 may determine that the voltage for charging the battery is not supplied from the external electronic device through the first pin 501. When it is identified that the voltage value (e.g., Vbus value) of the first pin 501 is greater (or higher) than the reference voltage value (Vref value) (e.g., output the high value (e.g., 1)), the power control circuit 500 may determine that the voltage for charging the battery is normally supplied from the external electronic device through the first pin 501.

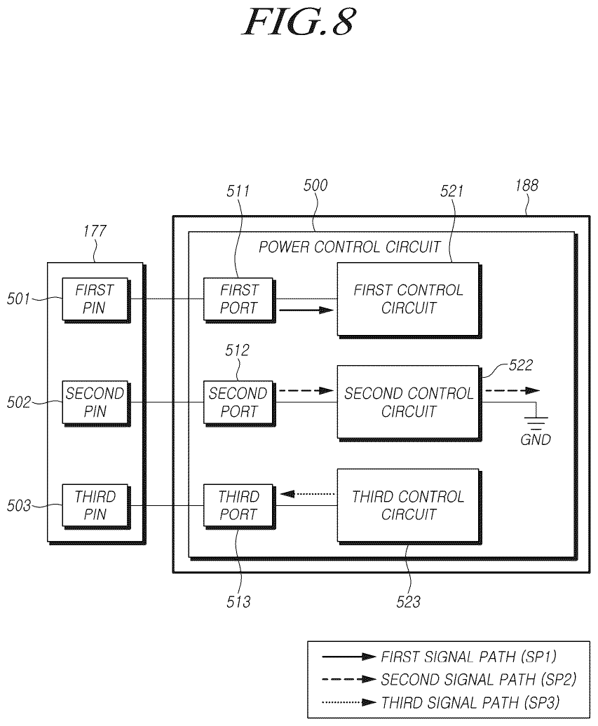

FIG. 8 is a block diagram illustrating an example power control circuit of an electronic device according to an embodiment of the disclosure.

In the embodiment of FIG. 8, the first pin 501 may be, e.g., the Vbus pin of FIG. 3B, the second pin 502 may be, e.g., the CC pin of FIG. 3B, and the third pin 503 may be, e.g., the DP/DN pin of FIG. 3B, but it will be understood that the disclosure is not limited thereto.

In the embodiment of FIG. 8, it may be understood that the operation (s performed by the power control circuit 500 is/are performed under the control of an electronic device (e.g., the electronic device 101 of FIG. 1 or the electronic device 200 of FIG. 2) or a processor (e.g., the processor 120 of FIG. 1) of the electronic device.

Referring to FIG. 8, the power control circuit 500 may include a first port 511 electrically connected to the first pin 501, a second port 512 electrically connected to the second pin 502, a third port 513 electrically connected to the third pin 503, a first control circuit 521 electrically connected to the first port, a second control circuit 522 electrically connected to the second port 512, and/or a third control circuit 523 electrically connected to the third port 513. The description of the first port 512, the second port 512, the first control circuit 521, and/or the second control circuit 522 may refer to the description of FIGS. 5, 6A, 6B and 7 (which may be referred to as FIGS. 5 to 7). A duplicate description thereof may not be repeated here.

According to an embodiment, the power control circuit 500 may be included in an electronic device (e.g., the electronic device 101 of FIG. 1 or the electronic device 200 of FIG. 2). For example, the power control circuit 500 may be included in a power management module (e.g., the power management module 188 of FIG. 1) of the electronic device.

According to an embodiment, the power control circuit 500 may be electrically connected to the interface 177 (e.g., the connector 210 of FIGS. 2 to 3B). For example, the power control circuit 500 may be electrically connected to the first pin 501, the second pin 502, and the third pin 503 of the interface 177 through the first port 511, the second port 512, and the third port 513, respectively. The first pin 510, the second pin 502, and the third pin 503 of the interface 177 may be spaced apart from each other in the interface 177.

According to an embodiment, the power control circuit 500 (e.g., the power management module 188 of FIG. 4) may supply power supplied from the external electronic device through the first pin 501 to the battery 189.

According to an embodiment, the first control circuit 521 may include a first circuit portion electrically connected to the first port 511 to detect the voltage state of the first port 511 supplied from the external electronic device through the first pin 501.

According to an embodiment, the second control circuit 522 may include a second circuit portion configured to selectively connect the second port 512 and the ground GND from the external electronic device.

According to an embodiment, the third control circuit 523 may include a third circuit portion configured to output a request signal for not supplying power (or voltage) from the external electronic device through the first pin 501 or for decreasing the value of the supplied power (or voltage) through the third port 513 (or the third pin 503), based on identifying that moisture is present in the interface 177. For example, the third control circuit 523 may include a third circuit portion configured to output a request signal for not supplying power (or voltage) from the external electronic device through the first pin 501 or for decreasing the value of the supplied power (or voltage) through the third port 513 (or the third pin 503), based on identifying that moisture is present in the connector while the external electronic device is connected to the connector. For example, the third control circuit 523 may include a third circuit portion configured to output a request signal for not supplying power (or voltage) from the external electronic device through the first pin 501 or for decreasing the value of the supplied power (or voltage) through the third port 513 (or the third pin 503), based on identifying that moisture is present in the connector and that the external electronic device is connected to the electronic device through the connector. For example, the third control circuit 523 may include a third circuit portion configured to determine whether a voltage value supplied through the first pin 501 is higher than or equal to the reference voltage when it is identified that moisture is present in the connector and the external electronic device is connected to the electronic device through the connector, and based on determining that the voltage value is higher than or equal to the reference voltage, output a request signal for not supplying power from the external electronic device through the first pin 501 or for decreasing the voltage value of power through the third port 513. The request signal output through the third port 513 may be transferred to the external electronic device.

According to an embodiment, the second control circuit 522 may include a second circuit portion configured to disconnect the second port 512 (or the second pin 502) from the ground GND, based on the voltage value supplied from the external electronic device through the first pin 501 remaining substantially the same after a specified time elapses after the request signal of the third control circuit 523 is output through the third port 513 (or the third pin 503). For example, the second control circuit 522 may include a second circuit portion configured to change the open/close state of the switch (e.g., the switch 610 of FIGS. 6A and 6B) from the first state (e.g., the close state) to the second state (e.g., the open state) to disconnect the second port 512 (or the second pin 502) from the ground GND, based on identifying that the voltage value supplied from the external electronic device through the first pin 501 is higher than the reference voltage after a specified time elapses after the request signal of the third control circuit 523 is output through the third port 513 (or the third pin 503).

According to an embodiment, the power control circuit 500 may include a first signal path SP1, a second signal path SP2, and/or a third signal path SP3. The description of the first signal path SP1 and the second signal path SP2 may refer to the description of FIG. 5. A duplicate description thereof is not repeated here.

According to an embodiment, the third signal path SP3 may include a third port 513 electrically connected to the third pin 503 and a third internal signal path portion electrically connected to the third port 513 and configured to output, through the third port 513 (or the third pin 503), a request signal for not supplying power (or voltage) from the external electronic device through the first pin 501 or for decreasing the value of the supplied power (or voltage), based on identifying that moisture is present in the interface 177. For example, the third signal path SP3 may include a third internal signal path portion configured to output a request signal for not supplying power (or voltage) from the external electronic device through the first pin 501 or for decreasing the value of the supplied power (or voltage) through the third port 513 (or the third pin 503), based on identifying that moisture is present in the connector while the external electronic device is connected to the connector. For example, the third signal path SP3 may include a third internal signal path portion configured to output a request signal for not supplying power (or voltage) from the external electronic device through the first pin 501 or for decreasing the value of the supplied power (or voltage) through the third port 513 (or the third pin 503), based on identifying that moisture is present in the connector and that the external electronic device is connected to the electronic device through the connector. For example, the third signal path SP3 may include a third internal signal path portion configured to, when it is identified that moisture is present in the connector and the external electronic device is connected to the electronic device through the connector, determine whether a voltage value supplied through the first pin 501 is higher than or equal to a reference voltage, and based on determining that the voltage value is higher than or equal to the reference voltage, output a request signal for not supplying power from the external electronic device through the first pin 501 or for decreasing the voltage value of power through the third port 513. The request signal output through the third port 513 may be transferred to the external electronic device. The third internal signal path portion may correspond to, e.g., the third circuit portion of the third control circuit 523.

According to an embodiment, the second signal path SP2 may include a second internal signal path portion configured to disconnect the second port 512 (or the second pin 502) from the ground GND, based on the voltage value supplied from the external electronic device through the first pin 501 remaining substantially the same after a specified time elapses after the request signal of the third control circuit 523 is output through the third port 513 (or the third pin 503). For example, the second signal path SP2 may include a second internal signal path portion configured to change the open/close state of the switch (e.g., the switch 610 of FIGS. 6A and 6B) from the first state (e.g., the close state) to the second state (e.g., the open state) to disconnect the second port 512 (or the second pin 502) from the ground GND, based on identifying that the voltage value supplied from the external electronic device through the first pin 501 is higher than the reference voltage after a specified time elapses after the request signal of the third control circuit 523 is output through the third port 513 (or the third pin 503). The second internal signal path portion may correspond to, e.g., the second circuit portion of the second control circuit 522.

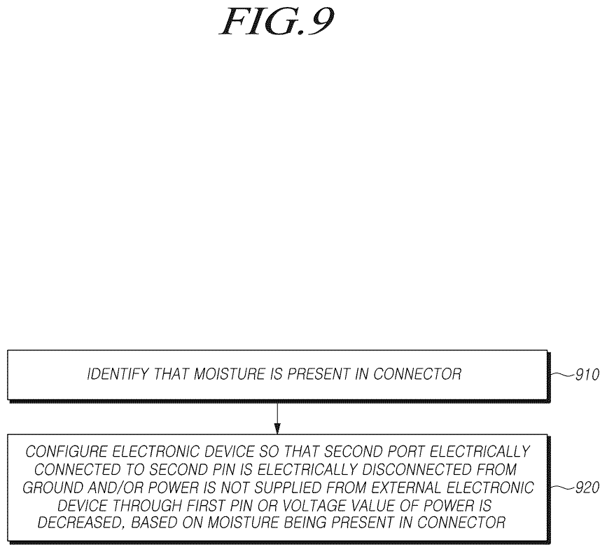

FIG. 9 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the method of operating the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

Referring to FIG. 9, in operation 910, the electronic device may identify that moisture is present in a connector (e.g., the interface 177 of FIG. 1 or the connector 210 of FIGS. 2 to 3B). For example, the electronic device may identify that moisture is present in the connector while the external electronic device (e.g., the external electronic device 410 of FIG. 4) is connected to the electronic device through the connector. For example, the electronic device may identify that moisture is present in the connector before the external electronic device is connected to the electronic device.

According to an embodiment, the electronic device may determine whether a resistance value (or a voltage of the second pin) corresponding to the second pin (e.g., the second pin 502 of FIGS. 5, 6A, 6B, 7 and 8 (which may be referred to as FIGS. 5 to 8)) is within a specified range, thereby identifying that moisture is present in the connector. For example, while the second pin is connected to the current source (e.g., the first current source 631 and/or the second current source 632 of FIG. 6B) through the second port (e.g., the second port 512 of FIGS. 5 to 8), the electronic device may determine whether the resistance value corresponding to the second pin is within the specified range using the comparator (e.g., the comparator 650 of FIG. 6B). Based on the resistance value corresponding to the second pin being within the specified range, the electronic device may identify that moisture is present in the connector. Based on the resistance value corresponding to the second pin not being within the specified range, the electronic device may identify that no moisture is present in the connector.

In operation 920, based on identifying that moisture is present in the connector, the electronic device may be configured so that the second port electrically connected to the second pin is electrically disconnected from the ground, and/or power is not supplied from the external electronic device through the first pin (e.g., the first pin 501 of FIGS. 5 to 8), or the voltage value of power supplied through the first pin is decreased. For example, based on identifying that moisture is present in the connector while the external electronic device is connected to the electronic device, the electronic device may be configured so that the second port electrically connected to the second pin is electrically disconnected from the ground, and/or power is not supplied from the external electronic device through the first pin, or the voltage value of power supplied through the first pin is decreased. For example, based on identifying that moisture is present in the connector and that the external electronic device is connected to the electronic device through the connector, the electronic device may be configured so that the second port electrically connected to the second pin is electrically disconnected from the ground, and/or power is not supplied from the external electronic device through the first pin, or the voltage value of power supplied through the first pin is decreased. In operation 920, since power is not supplied through the first pin or power having a low voltage value is supplied through the first pin, corrosion of the connector due to moisture may be prevented/reduced.

According to an embodiment, the electronic device may be configured to change the open/close state of the switch (e.g., the switch 610 of FIG. 6A or 6B) disposed between the second port and the ground from the first state (e.g., the close state) to the second state (e.g., the open state), thereby electrically disconnecting the second port from the ground. In this case, other switches (e.g., the first switch 641 and the second switch 642 of FIG. 6B) connected to the second port may also be set to the open state.

According to an embodiment, the voltage value of the power may be set to be lower (or less) than, e.g., a reference voltage (e.g., the reference voltage Vref of the comparator 710 of FIG. 7).

According to an embodiment, the electronic device may be configured to perform an operation (e.g., operation 910) of identifying (or determining) the presence of moisture in the connector and/or an operation (e.g., operation 920) of performing electrical disconnection between the second port and the ground before negotiation for determining charging power between the external electronic device and the electronic device is performed or completed. For example, operation 910 and/or operation 920 may be performed before negotiation for determining charging power between the external electronic device and the electronic device is performed or completed.

According to an embodiment, the electronic device may be configured to perform an operation (e.g., operation 910) of identifying the presence of moisture in the connector and/or an operation (e.g., operation 920) of performing electrical disconnection between the second port and the ground while negotiation for determining the charging power between the external electronic device and the electronic device is completed and the battery is charged by at least a portion of the power supplied by the external electronic device. For example, operation 910 and/or operation 920 may be performed while negotiation for determining charging power between the external electronic device and the electronic device is completed and the battery is charged by at least a portion of the power supplied by the external electronic device.

According to an embodiment, the electronic device may be configured to perform an operation (e.g., operation 910) of identifying the presence of moisture in the connector before the external electronic device and the electronic device are connected, and perform an operation (e.g., operation 920) of performing electrical disconnection between the second port and the ground after the external electronic device and the electronic device are connected (e.g., after negotiation for determining charging power between the external electronic device and the electronic device is performed or completed). For example, operation 910 may be performed before the external electronic device is connected to the electronic device, and operation 920 may be performed after the external electronic device is connected to the electronic device.

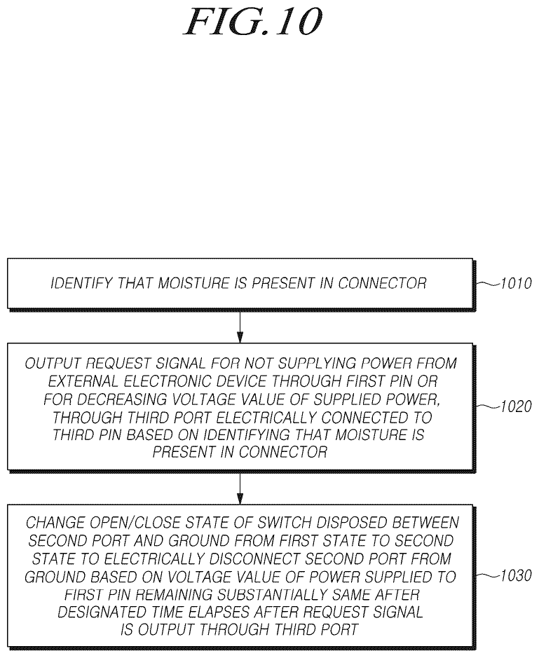

FIG. 10 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

Referring to FIG. 10, in operation 1010, the electronic device may identify that moisture is present in a connector (e.g., the interface 177 of FIG. 1 or the connector 210 of FIGS. 2 to 3B). For example, the electronic device may identify (or determine) that moisture is present in the connector while the external electronic device (e.g., the external electronic device 410 of FIG. 4) is connected to the electronic device through the connector. For example, the electronic device may identify that moisture is present in the connector before the external electronic device is connected to the electronic device.

According to an embodiment, the electronic device may determine whether a resistance value (or a voltage of the second pin) corresponding to the second pin (e.g., the second pin 502 of FIGS. 5 to 8) is within a specified range, thereby identifying that moisture is present in the connector. For example, while the second pin is connected to the current source (e.g., the first current source 631 or the second current source 632 of FIG. 6B) through the second port (e.g., the second port 512 of FIGS. 5 to 8), the electronic device may determine whether the resistance value corresponding to the second pin is within the specified range using the comparator (e.g., the comparator 650 of FIG. 6B). Based on the resistance value corresponding to the second pin being within the specified range, the electronic device may identify or determine that moisture is present in the connector. Based on the resistance value corresponding to the second pin not being within the specified range, the electronic device may identify or determine that no moisture is present in the connector.

In operation 1020, based on identifying that moisture is present in the connector, the electronic device may output a request signal (hereinafter, referred to as a power-related request signal or a request signal) for not supplying (or disconnecting) power from the external electronic device through the first pin (e.g., the first pin 501 of FIGS. 5 to 8) or decreasing the voltage value of the power supplied through the first pin through the third port (e.g., the third port 513 of FIG. 8) electrically connected to the third pin (e.g., the third pin 503 of FIG. 8). For example, based on identifying or determining that moisture is present in the connector while the external electronic device is connected to the electronic device, the electronic device may output the power-related request signal through the third port electrically connected to the third pin. For example, the electronic device may output the power-related request signal through the third port electrically connected to the third pin, based on determining that the resistance value is within a specified range while the external electronic device is connected to the electronic device. For example, the electronic device may output the power-related request signal through the third port based on identifying that moisture is present in the connector and that the external electronic device is connected to the electronic device through the connector. For example, when it is identified that moisture is present in the connector and the external electronic device is connected to the electronic device through the connector, the electronic device may determine whether the voltage value supplied through the first pin is higher than or equal to the reference voltage, and may output the power-related request signal through the third port based on determining that the voltage value supplied through the first pin is higher than or equal to the reference voltage. The request signal output through the third port may be transferred to the external electronic device. When the external electronic device supports, e.g., a protection function such as a hiccup function, the external electronic device may not supply power (or disconnect) through the first pin using the corresponding protection function or may decrease and provide the voltage value of the power supplied through the first pin in response to the request signal. According to the operation of the external electronic device based on the request signal, power may not be supplied through the first pin or power having a low voltage value may be supplied through the first pin, thereby preventing/reducing corrosion of the connector due to moisture.

In operation 1030, the electronic device may change the open/close state of the switch (e.g., the switch 610 of FIG. 6A or 6B) disposed between the second port and the ground from the first state (e.g., the close state) to the second state (e.g., the open state) so that the second port is electrically disconnected from the ground, based on the voltage value of the power supplied to the first pin remaining substantially the same after a specified time elapses after the request signal is output through the third port.

According to an embodiment, when the difference between the first voltage value which is the voltage value supplied to the first pin before the request signal, is output through the third port, and the second voltage value, which is the voltage value of the power supplied to the first pin after a specified time elapses after the request signal, is output through the third port is within the specified range, the electronic device may determine that the voltage value of the power supplied to the first pin remains substantially the same.

According to an embodiment, when the difference between the first voltage value which is the voltage value supplied to the first pin before the request signal is output through the third port and the second voltage value which is the voltage value of the power supplied to the first pin after the specified time elapses after the request signal is output through the third port is not within the specified range, the electronic device may determine that the voltage value of the power supplied to the first pin does not remain substantially the same.

According to an embodiment, when both the first voltage value, which is the voltage value supplied to the first pin before the request signal is output through the third port, and the second voltage value, which is the voltage value of the power supplied to the first pin after a specified time elapses after the request signal is output through the third port, are higher than the reference voltage value (e.g., the reference voltage Vref value of the comparator 710 of FIG. 7), the electronic device may determine that the voltage value of the power supplied to the first pin remains substantially the same.

According to an embodiment, when the first voltage value, which is the voltage value supplied to the first pin before the request signal is output through the third port, is higher than the reference voltage value (e.g., the reference voltage Vref value of the comparator 710 of FIG. 7), and the second voltage value, which is the voltage value of the power supplied to the first pin after the specified time elapses after the request signal is output through the third port, is lower (or less) than the reference voltage value, the electronic device may determine that the voltage value of the power supplied to the first pin does not remain substantially the same.

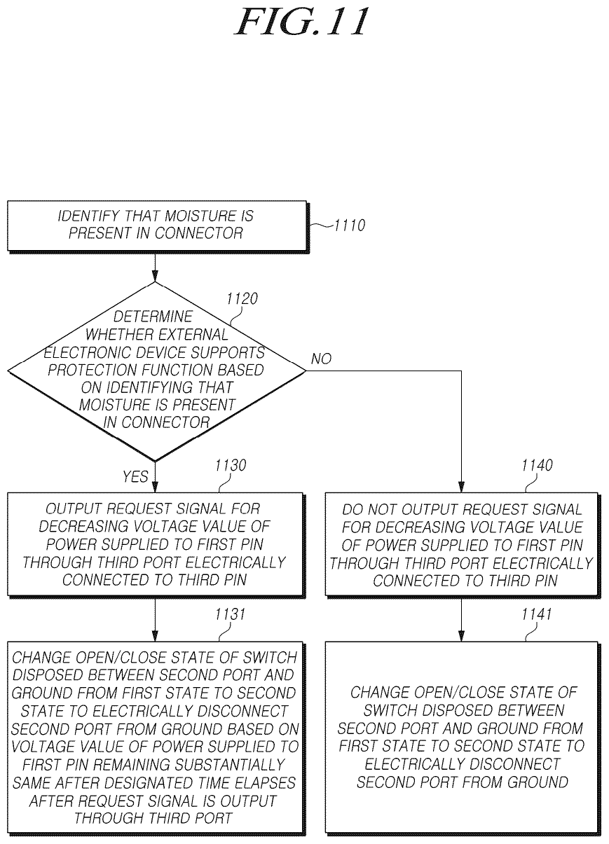

FIG. 11 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

Referring to FIG. 11, in operation 1110, the electronic device may identify that moisture is present in a connector (e.g., the interface 177 of FIG. 1 or the connector 210 of FIGS. 2, 3A and 3B (which may be referred to as FIGS. 2 to 3B)). For example, the electronic device may identify that moisture is present in the connector while the external electronic device (e.g., the external electronic device 410 of FIG. 4) is connected to the electronic device. The description of operation 1110 may refer to the description of operation 910 of FIG. 9 or operation 1010 of FIG. 10. A duplicate description thereof may not be repeated here.

In operation 1120, based on identifying (or determining) that moisture is present in the connector, the electronic device may determine (or identify) whether the external electronic device supports the protection function. For example, the electronic device may determine whether the external electronic device supports the protection function, based on identifying that moisture is present in the connector while the external electronic device is connected to the electronic device. For example, the electronic device may determine whether the external electronic device supports the protection function, based on identifying that moisture is present in the connector and that the external electronic device is connected to the electronic device. The protection function may be, e.g., a hiccup function, but is not limited thereto. Various types of overcurrent protection functions or overvoltage protection functions may be used as protection functions.

According to an embodiment, in the process of establishing the communication connection with the external electronic device through the second pin (e.g., the second pin 502 of FIGS. 5 to 8), the electronic device may determine whether the external electronic device supports the protection function based on the performance information about the external electronic device received from the external electronic device.

In operation 1130, based on determining that the external electronic device supports the protection function, the electronic device may output a request signal for not supplying (or disconnecting) power through the first pin (e.g., the first pin 501 of FIGS. 5 to 8) or decreasing the voltage value of the power supplied through the first pin through the third port (e.g., the third port 513 of FIGS. 5 to 8) electrically connected to the third pin (e.g., the third pin 503 of FIGS. 5 to 8). For the description of operation 1130, the description of operation 1020 of FIG. 10 may be referred to. Therefore, a duplicate description may not be repeated here.

In operation 1131, the electronic device may change the open/close state of the switch (e.g., the switch 610 of FIG. 6A or 6B) disposed between the second port and the ground from the first state (e.g., the close state) to the second state (e.g., the open state) so that the second port is electrically disconnected from the ground, based on the voltage value of the power supplied to the first pin remaining substantially the same after a specified time elapses after the request signal is output through the third port. For the description of operation 1131, the description of operation 1030 of FIG. 10 may be referred to. A duplicate description thereof may not be repeated here.

In operation 1140, based on determining (or identifying) that the external electronic device does not support the protection function, the electronic device may not output a request signal for not supplying (or disconnecting) power through the first pin or decreasing the voltage value of the power supplied through the first pin through the third port electrically connected to the third pin. For example, when the external electronic device does not support the protection function, the electronic device may not output the request signal through the third port electrically connected to the third pin. If the external electronic device does not support the protection function, even if the request signal is transmitted to the external electronic device, the external electronic device may not perform the protection function in response to the request signal, and thus transmitting the request signal corresponds to an unnecessary operation. The electronic device may selectively transmit the request signal only when required depending on the determination as to whether the external electronic device supports the protection function according to operation 1120, thereby increasing efficiency of use of power and resources.

In operation 1141, the electronic device may change the open/close state of the switch disposed between the second port and the ground from the first state (e.g., the close state) to the second state (e.g., the open state) so that the second port is electrically disconnected from the ground.

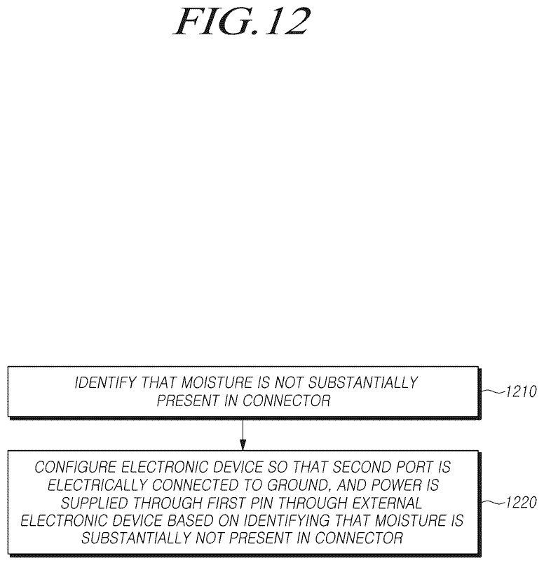

FIG. 12 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

According to an embodiment, operation 1210 and/or operation 1220 of FIG. 12 may be performed, e.g., after operation 920 of FIG. 9, after operation 1030 of FIG. 10, or after operation 1131 or 1140 of FIG. 11.

Referring to FIG. 12, in operation 1210, the electronic device may identify that moisture is not substantially present in the connector. For example, the electronic device may identify that moisture is not substantially present in the connector in a state in which the external electronic device is connected to the connector. For example, the electronic device may identify that moisture is not substantially present in the connector in a state in which the external electronic device is not connected to the connector.

According to an embodiment, the electronic device may determine whether the resistance value corresponding to the second pin (e.g., the second pin 502 of FIGS. 5 to 8) is within a specified range, thereby identifying that moisture is not substantially present in the connector (e.g., identifying that moisture is removed). For example, while the second pin is connected to the current source (e.g., the first current source 631 and/or the second current source 632 of FIG. 6B) through the second port (e.g., the second port 512 of FIG. 5 or 8), the electronic device may determine whether the resistance value corresponding to the second pin is within the specified range using the comparator (e.g., the comparator 650 of FIG. 6B). Based on the resistance value corresponding to the second pin being within the specified range, the electronic device may identify that moisture is present in the connector. Based on the resistance value corresponding to the second pin not being within the specified range, the electronic device may identify that no moisture is present in the connector.

In operation 1220, the electronic device may be configured so that the second port is electrically connected to the ground and power is supplied through the first pin through the external electronic device, based on identifying that moisture is not substantially present in the connector. For example, the electronic device may be configured so that the second port is electrically connected to the ground and power is supplied through the first pin through the external electronic device, based on identifying that moisture is not substantially present in the connector in a state in which the external electronic device is connected to the connector. For example, the electronic device may be configured so that the second port is electrically connected to the ground and power is supplied through the first pin through the external electronic device based on identifying that moisture is not substantially present in the connector and that the external electronic device is connected to the connector.

According to an embodiment, the electronic device may be configured to change the open/close state of the switch (e.g., the switch 610 of FIG. 6A or 6B) disposed between the second port and the ground from the second state (e.g., the open state) to the first state (e.g., the close state), thereby electrically connecting the second port to the ground. Based on identifying that the second port is electrically connected to the ground through a pull-down resistor (e.g., the resistor 620 of FIGS. 6A and 6B), the external electronic device may recognize the electronic device as a sink device and may provide power for charging the battery (e.g., the battery 189 of FIG. 1) of the electronic device through the first pin.

Through operations 1210 and 1220 of FIG. 12 described above, the electronic device may return to the normal state in which no moisture is present, and the external electronic device may supply power to the electronic device.

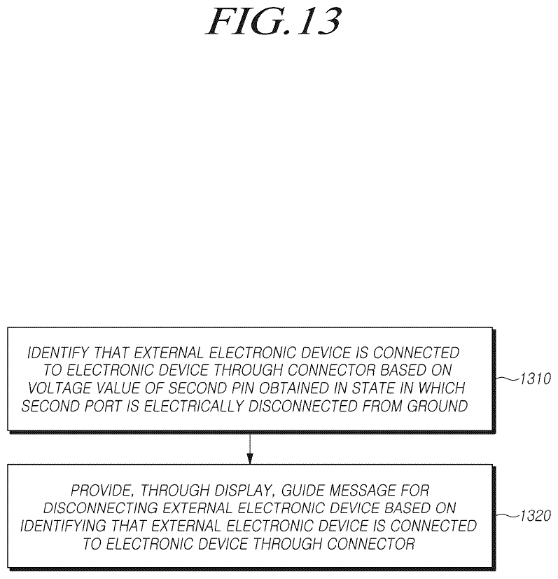

FIG. 13 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

According to an embodiment, operation 1310 and/or operation 1320 of FIG. 13 may be performed, e.g., after operation 920 of FIG. 9, after operation 1030 of FIG. 10, or after operation 1131 or 1140 of FIG. 11.

Referring to FIG. 13, in operation 1310, the electronic device may identify that the external electronic device is connected to the electronic device through the connector, based on the voltage value of the second pin (e.g., the second pin 502 of FIGS. 5 to 8) obtained in a state in which the second port (e.g., the second port 512 of FIGS. 5 to 8) is electrically disconnected from the ground. According to an embodiment, the electronic device may determine whether the voltage of the second pin is higher (e.g., greater) than the reference voltage, may identify that the external electronic device is connected to the electronic device through the connector when the voltage of the second pin is higher (e.g., greater) than the reference voltage and may identify that the external electronic device is not connected to the electronic device through the connector when the voltage of the second pin is lower (e.g., less) than the reference voltage. In operation 1310, the electronic device may measure the voltage of the second pin in a state in which the second pin (e.g., the CC pin of FIG. 3B) is electrically disconnected from the ground, thereby determining whether the external electronic device is still connected to the electronic device through the connector even though moisture is present in the connector.

In operation 1320, the electronic device may provide, through a display, a guide message for disconnecting the external electronic device, based on identifying that the external electronic device is connected to the electronic device through the connector.

According to an embodiment, the electronic device may display the guide message for disconnecting the external electronic device through a display (e.g., the display module 160 of FIG. 1). According to an embodiment, the electronic device may output the guide message for disconnecting the external electronic device through a speaker.

According to an embodiment, the guide message may include a message such as “Please remove the charger from the electronic device.”

According to an embodiment, the electronic device may display information (e.g., an icon) displaying the detection of moisture in the connector, together with or separately from the guide message, on the display.

Through the guide message provided through operation 1320, the user may identify that moisture is present and remove the external electronic device (e.g., the charging device) from the electronic device. Accordingly, it is possible to prevent/reduce the electronic device from being corroded by moisture.

FIG. 14 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

Referring to FIG. 14, in operation 1410, the electronic device may operate in the normal state.

According to an embodiment, in the normal state, the electronic device may control the switches (e.g., the switch 610, the first switch 641, and/or the second switch 642 of FIG. 6B) included in the second control circuit (e.g., the second control circuit 522 of FIGS. 5 to 8) electrically connected to the CC pin (e.g., the second pin 502 of FIGS. 5 to 8) through the second port (e.g., the second port 512 of FIGS. 5 to 8) to selectively connect any one of the pull-down resistor Rd (e.g., the resistor 620 of FIGS. 6A and 6B), the first current source (e.g., the first current source 631 of FIG. 6B), and the second current source (e.g., the second current source 632 of FIG. 6B) to the CC pin in the corresponding time interval. Accordingly, in the normal state, only one of the pull-down resistor, the first current source, and the second current source may be connected to the CC pin in each time interval.

For example, in the first time interval (e.g., the first time interval, the third time interval, or the seventh time interval in Table 3) of the normal state, the electronic device may control the switch 610 in the close state and may control the first switch 641 and the second switch 642 in the open state, thereby electrically connecting the second pin to the ground through the pull-down resistor Rd.

For example, in the second time interval (e.g., the second time interval in Table 1 or the fourth time interval in Table 2) which is the next time interval of the first time interval in the normal state, the electronic device may control the first switch 641 in the close state and may control the switch 610 and the second switch 642 in the open state, thereby electrically connecting the first current source 631 to the CC pin. The electronic device may determine whether the CC pin is in an abnormal state using the first current source 631.

For example, in the third time interval (e.g., the fifth time interval in Table 2 or the ninth time interval in Table 3) which is the next time interval of the second time interval in the normal state, the electronic device may control the second switch 642 in the close state and may control the switch 610 and the first switch 641 in the open state, thereby electrically connecting the second current source 632 to the CC pin. According to an embodiment, the second switch 642 may be controlled in the close state based on determining that the CC pin is in the abnormal state. The electronic device may determine whether moisture is present in the CC pin in the abnormal state using the second current source 632.

According to an embodiment, the electronic device may sequentially and repeatedly perform the operations of the first time interval, the second time interval, and the third time interval described above.

According to an embodiment, when the external electronic device (e.g., the external electronic device 410 of FIG. 4) is not connected to the electronic device through a connector (e.g., the interface 177 of FIG. 1 or the connector 210 of FIGS. 2 to 3B), the electronic device may operate in the normal state.

According to an embodiment, in a state in which the external electronic device (e.g., the external electronic device 410 of FIG. 4) is connected to the electronic device through the connector (e.g., the interface 177 of FIG. 1 or the connector 210 of FIG. 2), the electronic device may operate in the normal state until moisture in the connector is detected.

In operation 1420, the electronic device may identify that moisture is present in the connector. According to an embodiment, the electronic device may identify or determine that moisture is present in at least one pin of the connector. The description of operation 1420 may refer to the description of operation 1010 of FIG. 10 or operation 1110 of FIG. 11. A duplicate description thereof may not be repeated here.

In operation 1430, the electronic device may be configured so that the CC pin is electrically connected to the ground, based on identifying that moisture is present in the connector. For example, the electronic device may be configured to control the switch 610 in the close state so that the CC pin is electrically connected to the ground through the pull-down resistor 620. As it is identified that moisture is present, the CC pin is electrically connected to the ground, so that the electronic device may make (or operate) the voltage of the CC pin in a low state (e.g., a state close to OV) and recognize that the external electronic device is connected to the electronic device through the connector.

In operation 1440, the electronic device may identify that the external electronic device is connected to the electronic device through the connector. According to an embodiment, the electronic device may identify the voltage of the CC pin in a state in which the CC pin is electrically connected to the ground through the pull-down resistor, thereby identifying that the external electronic device is connected to the electronic device through the connector.

In operation 1450, the electronic device may determine whether the voltage (the first Vbus voltage) supplied from the external electronic device to the electronic device through the Vbus pin (e.g., the first pin 501 of FIGS. 5 to 8) is higher (e.g., greater) than the reference voltage Vref. According to an embodiment, the electronic device may determine whether the first Vbus voltage is higher than the Vref voltage using the output value of the comparator (e.g., the comparator 710 of FIG. 7) included in the first control circuit (e.g., the first control circuit 521 of FIGS. 5 to 8) connected to the Vbus pin through the first port (e.g., the first port 512 of FIGS. 5 to 8). For example, when the output value of the comparator is the first value (e.g., 1), the electronic device may determine that the first Vbus voltage is higher than the Vref voltage. When the first Vbus voltage is higher than the Vref voltage, operation 1460 may be performed. For example, when the output value of the comparator is the second value (e.g., 0), the electronic device may determine that the first Vbus voltage is lower (e.g., less) than the Vref voltage. When the first Vbus voltage is lower than the Vref voltage, operation 1430 may be performed again.

In operation 1460, based on Vbus>Vref in operation 1450, the electronic device may transmit a request signal for not supplying the Vbus voltage through the Vbus pin from the external electronic device or decreasing the Vbus voltage to the external electronic device through the DP/DN pin (e.g., the third pin 503 of FIGS. 5 to 8). According to an embodiment, the request signal may be generated based on processing (DP GND processing) of electrically connecting the DP/DN pin to the ground GND. For example, the request signal may correspond to the voltage value of the DP/DN pin generated through processing of electrically connecting the DP/DN pin to the ground GND.

In operation 1470, the electronic device may wait for a specified time (e.g., five seconds). According to an embodiment, the electronic device may wait for the specified time after transmitting the request signal. According to an embodiment, the specified time when the electronic device waits may be longer than the minimum time taken for the external electronic device to perform the protection function (e.g., a hiccup function) in response to the request signal.

In operation 1480, the electronic device may determine whether the voltage (the second Vbus voltage) supplied from the external electronic device to the electronic device through the Vbus pin after the specified time is higher (e.g., greater) than the reference voltage (the Vref voltage). According to an embodiment, the electronic device may determine whether the second Vbus voltage is higher than the Vref voltage using the output value of the comparator included in the first control circuit connected to the first pin through the first port. For example, if the output value of the comparator is the first value (e.g., one), the electronic device may determine that the second Vbus voltage is higher than the Vref voltage. When the second Vbus voltage is higher than the Vref voltage, operation 1490 may be performed. For example, when the output value of the comparator is the second value (e.g., 0), the electronic device may determine that the second Vbus voltage is lower than the Vref voltage. When the second Vbus voltage is lower (or less) than or equal to the Vref voltage, operation 1491 may be performed.

In operation 1490, when Vbus>Vref in operation 1480, the electronic device may be configured so that the CC pin is electrically disconnected from the ground. The description of operation 1490 may refer to the description of operation 1030 of FIG. 10. Therefore, a duplicate description may not be repeated here.

In operation 1491, the electronic device may maintain an electrical connection between the CC pin and the ground.

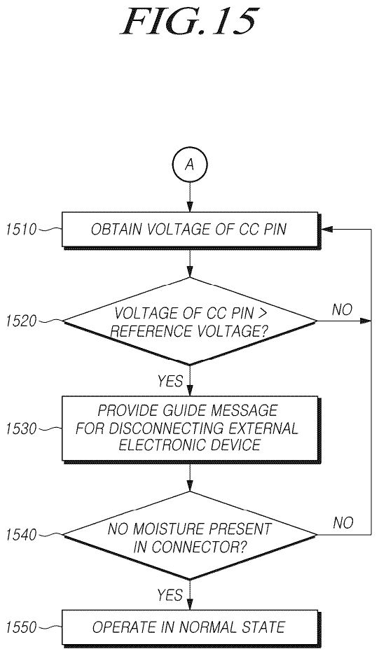

FIG. 15 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

The method of FIG. 15 may be performed, e.g., after operation 1490 of FIG. 14.

Referring to FIG. 15, in operation 1510, the electronic device may obtain the voltage of the CC pin (e.g., the second pin 502 of FIGS. 5 to 8). According to an embodiment, the electronic device may measure the voltage of the CC pin in a state in which the CC pin is electrically disconnected from the ground GND. The electronic device may measure the voltage of the CC pin in a state in which the CC pin is electrically disconnected from the ground, thereby determining whether the external electronic device is still connected to the electronic device through the connector even though moisture is present in the connector.

In operation 1520, the electronic device may determine whether the voltage of the CC pin is higher (e.g., greater) than the reference voltage. According to an embodiment, the electronic device may determine whether the voltage of the CC pin obtained (or measured) in a state in which the CC pin is electrically disconnected from the ground is higher than the reference voltage. When the voltage of the CC pin is higher than the reference voltage, operation 1530 may be performed. When the voltage of the CC pin is lower (e.g., less) than the reference voltage, operation 1510 may be performed.

In operation 1530, the electronic device may provide a guide message for disconnecting the external electronic device when the voltage of the CC pin is greater than the reference voltage in operation 1520. The description of operation 1530 may refer to the description of operation 1320 of FIG. 13. Therefore, a duplicate description may not be repeated here.

In operation 1540, the electronic device may determine whether moisture is (substantially) not present in the connector. The description of operation 1540 may refer to the description of operation 1210 of FIG. 12. Therefore, a duplicate description may not be repeated here. When no moisture is present in the connector, operation 1550 may be performed. When moisture is present in the connector, operation 1510 may be performed again.

In operation 1550, the electronic device may operate in the normal state. The description of operation 1550 may refer to the description of operation 1410 of FIG. 14. A duplicate description thereof may not be repeated here.

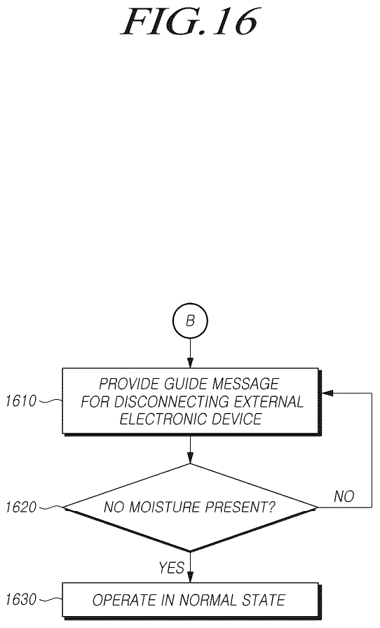

FIG. 16 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

The method of FIG. 16 may be performed, e.g., after operation 1491 of FIG. 14.

Referring to FIG. 16, in operation 1610, the electronic device may provide a guide message for disconnecting the external electronic device. The description of operation 1610 may refer to the description of operation 1210 of FIG. 12. Therefore, a duplicate description may not be repeated here.

In operation 1620, the electronic device may determine whether moisture is present in the connector. The description of operation 1620 may refer to the description of operation 1210 of FIG. 12. Therefore, a duplicate description may not be repeated here. When no moisture is present in the connector, operation 1630 may be performed. When moisture is present in the connector, operation 1610 may be performed again.

In operation 1630, the electronic device may operate in the normal state. The description of operation 1630 may refer to the description of operation 1410 of FIG. 14. A duplicate description thereof may not be repeated here.

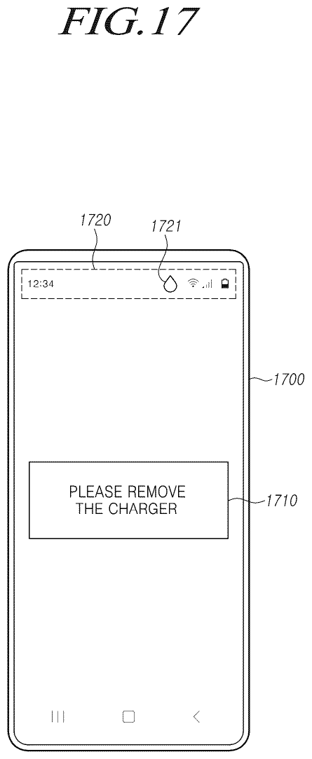

FIG. 17 is a diagram illustrating an example screen in which an electronic device provides a guide message for disconnecting an external electronic device, according to an embodiment of the disclosure.

Referring to FIG. 17, according to an embodiment, an electronic device (e.g., the electronic device 101 of FIG. 1) may display a screen 1700 including a guide message 1710 for disconnecting an external electronic device (e.g., a charger) through a display (e.g., the display module 160).

According to an embodiment, the guide message 1710 may be included in the screen 1700, together with information 1721 (e.g., an icon) indicating the detection of moisture in the connector. For example, information 1721 indicating the detection of moisture in the connector may be displayed on the status bar 1720 in the screen 1700. The user may identify the displayed information and remove the external electronic device from the electronic device. Accordingly, corrosion due to moisture may be prevented/reduced.

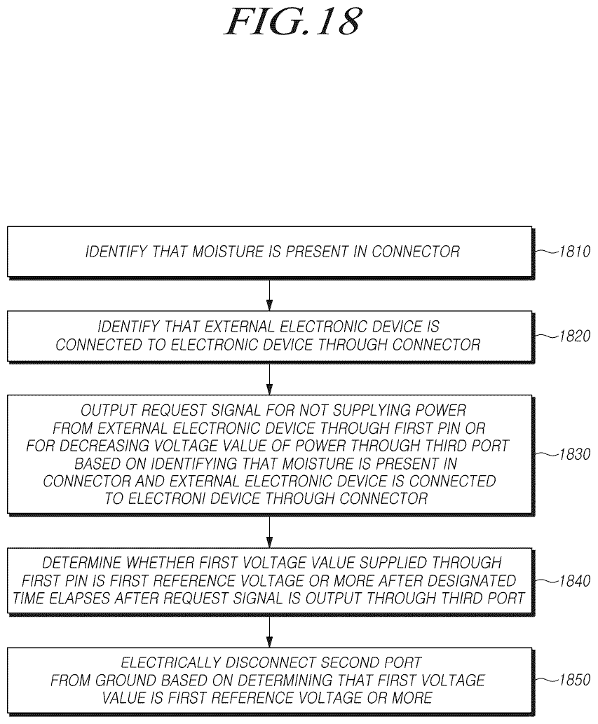

FIG. 18 is a flowchart illustrating an example method of operating an electronic device according to an embodiment of the disclosure.

In the following embodiments, each operation may be performed sequentially, but is not necessarily performed sequentially. For example, the order of each operation may be changed, and at least two operations may be performed in parallel. In the following embodiments, some of the operations may be omitted, or an additional operation may be further performed.

According to an embodiment, the operation method of the electronic device (e.g., the electronic device 101 of FIG. 1 or the electronic device 200 of FIG. 2) may be performed by a processor (e.g., the processor 120 of FIG. 1) of the electronic device or a power control circuit (e.g., the power control circuit 500 of FIGS. 5 to 8) of the electronic device.

Referring to FIG. 18, in operation 1810, the electronic device may identify that moisture is present in the connector. The description of operation 1810 may refer to, e.g., the description of operation 1420 of FIG. 14. A duplicate description thereof may not be repeated here.

In operation 1820, the electronic device may identify that the external electronic device is connected to the electronic device through the connector. According to an embodiment, operation 1820 may be performed after operation 1810, before operation 1810, or in parallel with operation 1810. The description of operation 1820 may refer to, e.g., the description of operation 1440 of FIG. 14. A duplicate description thereof may not be repeated here.

In operation 1830, based on identifying that moisture is present in the connector and that the external electronic device is connected to the electronic device through the connector, the electronic device may output a request signal for not supplying (or disconnecting) power from the external electronic device through the first pin or for decreasing the voltage value of the power through the third port. The description of operation 1830 may refer to, e.g., the description of operations 1450 to 1460 of FIG. 14. A duplicate description thereof may not be repeated here.

In operation 1840, the electronic device may determine whether the first voltage value supplied through the first pin is higher than or equal to the first reference voltage after the specified time elapses after the request signal is output through the third port. The description of operation 1840 may refer to the description of operations 1470 to 1480 of FIG. 14. A duplicate description thereof may not be repeated here.

In operation 1850, based on determining that the first voltage value is greater than or equal to the first reference voltage, the second port may be electrically disconnected from the ground. The description of operation 1850 may refer to, e.g., the description of operation 1490 of FIG. 14. A duplicate description thereof may not be repeated here.

According to an embodiment, the electronic device may obtain the voltage value of the second pin in a state in which the second port is electrically disconnected from the ground, and may provide a guide message for disconnection of the external electronic device, based on the voltage value of the second pin.

According to an embodiment, the electronic device may determine whether the voltage value of the second pin is higher than or equal to the second reference voltage, may provide a guide message for disconnection of the external electronic device when it is determined that the voltage value of the second pin is higher than or equal to the second reference voltage, and may not provide the guide message for disconnection of the external electronic device when it is determined that the voltage value of the second pin is less than the second reference voltage.

According to an embodiment, when it is identified that moisture is present in the connector and the external electronic device is connected to the electronic device through the connector, the electronic device may determine whether the second voltage value, supplied through the first pin is higher than or equal to the first reference voltage, and based on determining that the second voltage value is higher than or equal to the first reference voltage, the electronic device may output a request signal for not supplying the power from the external electronic device through the first pin or for decreasing the voltage value of the power through the third port.

According to an embodiment, the electronic device may identify or determine that the moisture is present in the connector based on the resistance value corresponding to the second pin being within a specified range, and in response to identifying that the moisture is present in the connector, the electronic device may control the switch to be closed in order for the second port to be electrically connected to the ground.

According to an embodiment, the second circuit may include a switch disposed between the second port and the ground, and the electronic device may control the switch to be opened so that the second port is electrically disconnected from the ground.

According to an embodiment, the second circuit may further include a current source and a comparator connected in parallel with the switch with respect to the second port, and the electronic device may determine whether the resistance value is within the specified range using the comparator while the second pin is electrically connected with the current source through the second port.

According to an embodiment, the second port may be electrically connected to the ground, and the power may be supplied from the external electronic device through the first pin, based on the moisture being substantially removed from the connector while the external electronic device is connected to the connector.

According to an embodiment, the electronic device may at least partially increase the voltage value of the power supplied through the first port after the second port is electrically connected to the ground.

According to an example embodiment, an electronic device may be provided. The electronic device may include a battery. The electronic device may include a connector including a first pin and a second pin spaced apart from each other and configured to be connected to an external electronic device. The first pin may be configured to receive power for charging the battery from the external electronic device. The electronic device may include a power control circuit electrically connected to the connector and including a first signal path and a second signal path. The first signal path may include a first port electrically connected to the first pin and a first internal signal path portion connected to the first port and configured to transfer the power supplied from the external electronic device to the battery. The second signal path may include a second port electrically connected to the second pin and a second internal signal path portion configured to selectively connect the second port and a ground. The second internal signal path portion may be configured so that the second port is electrically disconnected from the ground and the power is not supplied from the external electronic device through the first pin or a voltage value of the power is decreased, based on a presence of moisture in the connector while the external electronic device is connected to the connector.

According to an example embodiment, the second internal signal path portion may include a switch disposed between the second port and the ground. The power control circuit may be configured to perform the electrical disconnection between the second port and the ground based on the switch being opened.

According to an example embodiment, the power control circuit may be configured to identify the presence of the moisture in the connector based on a resistance value corresponding to the second pin being within a specified range.

According to an example embodiment, the second internal signal path portion may further include a current source and a comparator connected in parallel with the switch for the second port. The power control circuit may be configured to determine whether the resistance value is within the specified range using the comparator while the second pin is electrically connected to the current source through the second port.

According to an example embodiment, the connector may further include a third pin spaced apart from each of the first pin and the second pin. The power control circuit may further include a third port electrically connected to the third pin. The power control circuit may be configured to output a request signal for decreasing the voltage value of the power through the third port, based on the resistance value being within the specified range while the external electronic device is connected to the connector, and change a state of the switch from a first state to a second state so that the second port is electrically disconnected from the ground, based on the voltage value supplied through the first pin remaining substantially the same after a specified time elapses after the request signal is output through the third port.

According to an example embodiment, the power control circuit may be configured to refrain from outputting the request signal to the external electronic device through the third port before the second port is electrically disconnected from the ground, based on identifying that the external electronic device does not support a hiccup function.

According to an example embodiment, the second internal signal path portion may be configured so that the second port is electrically connected to the ground and the power is supplied from the external electronic device through the first pin, based on the moisture being substantially removed from the connector while the external electronic device is connected to the connector.

According to an example embodiment, the voltage value of the power supplied through the first port may be configured to at least partially increase after the second port is electrically connected to the ground.

According to an example embodiment, the second internal signal path portion may include a switch disposed between the second port and the ground. The power control circuit may be configured to change a state of the switch from a second state to a first state so that the second port is electrically connected to the ground, based on a resistance value corresponding to the second pin not being within a specified range.

According to an example embodiment, the power control circuit may be configured to, before negotiation for determining charging power between the external electronic device and the electronic device, identify the presence of the moisture in the connector and perform the electrical disconnection between the second port and the ground.

According to an example embodiment, the power control circuit may be configured to identify the presence of the moisture in the connector and perform the electrical disconnection between the second port and the ground while negotiation for determining charging power between the external electronic device and the electronic device is completed and at least a portion of the power charges the battery.

According to an example embodiment, an electronic device may be provided. The electronic device may include a battery and a connector including a first pin, a second pin, and a third pin configured to be connected to an external electronic device. The electronic device may include a power management module comprising power management circuitry electrically connected to the connector and including a first circuit, a second circuit, and a third circuit 523 The first circuit may be connected to a first port electrically connected to the first pin and be configured to transfer power supplied from the external electronic device through the first pin to the battery. The second circuit may be connected to a second port electrically connected to the second pin and be configured to selectively connect the second port and ground. The third circuit may be connected to a third port electrically connected to the third pin and is configured to transmit a signal to the external electronic device through the third port. The electronic device may include a memory including one or more storage media storing instructions and at least one processor including processing circuitry. At least one processor, individually and/or collectively, may be configured to execute the instructions and to cause the electronic device to perform at least one operation. The at least one operation may include identifying that moisture is present in the connector. The at least one operation may include identifying that the external electronic device is connected to the electronic device through the connector. The at least one operation may include, based on identifying that the moisture is present in the connector and the external electronic device is connected to the electronic device through the connector, outputting a request signal for not supplying the power from the external electronic device through the first pin or for decreasing a voltage value of the power through the third port. The at least one operation may include determining whether a first voltage value supplied through the first pin is greater than or equal to a first reference voltage after a specified time elapses after the request signal is output through the third port. The at least one operation may include electrically disconnecting the second port from the ground, based on determining that the first voltage value is greater than or equal to the first reference voltage.

According to an example embodiment, the at least one operation may include obtaining the voltage value of the second pin in a state in which the second port is electrically disconnected from the ground and providing a guide message for disconnection of the external electronic device, based on the voltage value of the second pin.

According to an example embodiment, the at least one operation may include: determining whether the voltage value of the second pin is greater than or equal to the second reference voltage, providing a guide message for disconnection of the external electronic device based on determining that the voltage value of the second pin is greater than or equal to the second reference voltage, and not providing the guide message for disconnection of the external electronic device based on determining that the voltage value of the second pin is less than the second reference voltage.

According to an example embodiment, the at least one operation may include, based on identifying that moisture is present in the connector and the external electronic device is connected to the electronic device through the connector, determining whether the second voltage value supplied through the first pin is greater than or equal to the first reference voltage, and based on determining that the second voltage value is greater than or equal to the first reference voltage, outputting a request signal for not supplying the power from the external electronic device through the first pin or for decreasing the voltage value of the power through the third port.

According to an example embodiment, the at least one operation may include identifying that the moisture is present in the connector based on the resistance value corresponding to the second pin being within a specified range, and in response to identifying that the moisture is present in the connector, controlling the switch to be closed to electrically connect the second port to the ground before the external electronic device is connected to the electronic device through the connector.

According to an example embodiment, the second circuit may include a switch disposed between the second port and the ground, and the at least one operation may include controlling the switch to be opened so that the second port is electrically disconnected from the ground.

According to an example embodiment, the second circuit may further include a current source and a comparator connected in parallel with the switch with respect to the second port, and the at least one operation may include determining whether the resistance value is within the specified range using the comparator while the second pin is electrically connected with the current source through the second port.

According to an example embodiment, the at least one operation may include electrically connecting the second port to the ground and supplying the power from the external electronic device through the first pin, based on the moisture not being substantially present in the connector while the external electronic device is connected to the connector.

According to an example embodiment, at least one operation may include at least partially increasing the voltage value of the power supplied through the first port after the second port is electrically connected to the ground.

The various example embodiments of the disclosure and terms used therein are not intended to limit the technical features described in the disclosure to specific embodiments, and should be understood to include various modifications, equivalents, or substitutes of the various embodiments. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wired), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

The disclosure may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device, comprising:
a battery;
a connector including a first pin and a second pin spaced apart from each other and configured to be connected to an external electronic device, the first pin configured to receive power for charging the battery from the external electronic device; and
a power control circuit electrically connected to the connector and including a first signal path and a second signal path,
wherein the first signal path includes a first port electrically connected to the first pin and a first internal signal path portion connected to the first port and configured to transfer power supplied from the external electronic device to the battery,
wherein the second signal path includes a second port electrically connected to the second pin and a second internal signal path portion configured to selectively connect the second port and a ground, and
wherein the second internal signal path portion is configured so that the second port is electrically disconnected from the ground and power is not supplied from the external electronic device through the first pin or a voltage value of the power is decreased, based on a presence of moisture in the connector while the external electronic device is connected to the connector.

2. The electronic device of claim 1, wherein the second internal signal path portion includes a switch disposed between the second port and the ground, and
wherein the power control circuit is configured to electrically disconnect the second port and the ground based on the switch being opened.

3. The electronic device of claim 2, wherein the power control circuit is configured to identify the presence of the moisture in the connector based on a resistance value corresponding to the second pin being within a specified range.

4. The electronic device of claim 3, wherein the second internal signal path portion further includes a current source and a comparator connected in parallel with the switch for the second port, and
wherein the power control circuit is configured to determine whether the resistance value is within the specified range using the comparator while the second pin is electrically connected to the current source through the second port.

5. The electronic device of claim 3, wherein the connector further includes a third pin spaced apart from each of the first pin and the second pin,
wherein the power control circuit further includes a third port electrically connected to the third pin, and
wherein the power control circuit is configured to:
output a request signal for decreasing the voltage value of the power through the third port, based on the resistance value being within the specified range while the external electronic device is connected to the connector; and
change a state of the switch from a first state to a second state so that the second port is electrically disconnected from the ground, based on the voltage value supplied through the first pin remaining substantially the same after a specified time elapses after the request signal is output through the third port.

6. The electronic device of claim 5, wherein the power control circuit is configured to refrain from outputting the request signal to the external electronic device through the third port before the second port is electrically disconnected from the ground, based on identifying that the external electronic device does not support a hiccup function.

7. The electronic device of claim 1, wherein the second internal signal path portion is configured so that the second port is electrically connected to the ground and the power is supplied from the external electronic device through the first pin, based on the moisture being substantially absent from the connector while the external electronic device is connected to the connector.

8. The electronic device of claim 7, wherein the voltage value of the power supplied through the first port is configured to at least partially increase after the second port is electrically connected to the ground.

9. The electronic device of claim 7, wherein the second internal signal path portion includes a switch disposed between the second port and the ground, and
wherein the power control circuit is configured to change a state of the switch from a second state to a first state so that the second port is electrically connected to the ground, based on a resistance value corresponding to the second pin not being within a specified range.

10. The electronic device of claim 1, wherein the power control circuit is configured to, before negotiation for determining charging power between the external electronic device and the electronic device, identify the presence of the moisture in the connector and perform the electrical disconnection between the second port and the ground.

11. The electronic device of claim 1, wherein the power control circuit is configured to identify the presence of the moisture in the connector and electrically disconnect the second port and the ground while negotiation for determining charging power between the external electronic device and the electronic device is completed and at least a portion of the power charges the battery.

12. An electronic device, comprising:
a battery;
a connector including a first pin, a second pin, and a third pin configured to be connected to an external electronic device;
a power management module comprising power management circuitry electrically connected to the connector and including a first circuit, a second circuit, and a third circuit, wherein the first circuit is connected to a first port electrically connected to the first pin and is configured to transfer power supplied from the external electronic device through the first pin to the battery, wherein the second circuit is connected to a second port electrically connected to the second pin and is configured to selectively connect the second port or the ground, and wherein the third circuit is connected to a third port electrically connected to the third pin and is configured to transmit a signal to the external electronic device through the third port;
memory including one or more storage media storing instructions; and
at least one processor comprising processing circuitry,
wherein at least one processor, individually and/or collectively, is configured to execute the instructions and to cause the electronic device to:
identify that moisture is present in the connector;
identify that the external electronic device is connected to the electronic device through the connector;
based on identifying that the moisture is present in the connector and the external electronic device is connected to the electronic device through the connector, output a request signal for not supplying the power from the external electronic device through the first pin or for decreasing a voltage value of the power through the third port;
determine whether a first voltage value supplied through the first pin is greater than or equal to a first reference voltage after a specified time elapses after the request signal is output through the third port; and
electrically disconnect the second port from the ground, based on determining that the first voltage value is greater than or equal to the first reference voltage.

13. The electronic device of claim 12, wherein at least one processor, individually and/or collectively, is configured to cause the electronic device to:
obtain the voltage value of the second pin in a state in which the second port is electrically disconnected from the ground; and
provide a guide message for disconnecting the external electronic device based on the voltage value of the second pin.

14. The electronic device of claim 13, wherein at least one processor, individually and/or collectively, is configured to cause the electronic device to:
determine whether the voltage value of the second pin is greater than or equal to a second reference voltage;
provide the guide message for disconnecting the external electronic device based on determining that the voltage value of the second pin is greater than or equal to the second reference voltage; and
not provide the guide message for disconnecting the external electronic device based on determining that the voltage value of the second pin is less than the second reference voltage.

15. The electronic device of claim 12, wherein at least one processor, individually and/or collectively, is configured to cause the electronic device to:
based on identifying that the moisture is present in the connector and the external electronic device is connected to the electronic device through the connector, determine whether a second voltage value supplied through the first pin is greater than or equal to a first reference voltage; and
output a request signal for not supplying the power from the external electronic device through the first pin or for decreasing a voltage value of the power through the third port, based on determining that the second voltage value is equal to or greater than the first reference voltage.

16. The electronic device of claim 12, wherein at least one processor, individually and/or collectively, is configured to cause the electronic device to:
identify the presence of the moisture in the connector based on a resistance value corresponding to the second pin being within a specified range; and
in response to identifying that the moisture is present in the connector, control the switch to be closed in order for the second port to be electrically connected to the ground before the external electronic device is connected to the electronic device through the connector.

17. The electronic device of claim 12, wherein the second circuit includes a switch disposed between the second port and the ground, and
wherein at least one processor, individually and/or collectively, is configured to cause the electronic device to control the switch to be opened in order for the second port to be electrically disconnected from the ground.

18. The electronic device of claim 17, wherein the second circuit further includes a current source and a comparator connected in parallel with the switch for the second port, and
wherein at least one processor, individually and/or collectively, is configured to cause the electronic device to determine whether the resistance value is within the specified range using the comparator while the second pin is electrically connected to the current source through the second port.

19. The electronic device of claim 12, wherein at least one processor, individually and/or collectively, is configured to cause the electronic device to electrically connect the second port to the ground and supply the power from the external electronic device through the first pin, based on the moisture being substantially absent from the connector while the external electronic device is connected to the connector.

20. The electronic device of claim 19, wherein at least one processor, individually and/or collectively, is configured to cause the electronic device to at least partially increase the voltage value of the power supplied through the first port after the second port is electrically connected to the ground.
